(19) United States
(12) Patent Application Publication
(10) Pub. No.: US 2020/0282424 A1
(43) Pub. Date: Sep. 10, 2020

(54) OPTICALLY TRANSPARENT MICROMACHINED ULTRASONIC TRANSDUCER (CMUT)

(71) Applicant: NORTH CAROLINA STATE UNIVERSITY, Raleigh, NC (US)

(72) Inventors: Omer ORALKAN, Raleigh, NC (US); Feysel Yalcin YAMANER, Raleigh, NC (US); Xiao ZHANG, Raleigh, NC (US)

(21) Appl. No.: 16/637,854

(22) PCT Filed: Aug. 10, 2018
(86) PCT No.: PCT/US2018/046170

§ 371 Date: Feb. 10, 2020

Related U.S. Application Data
(60) Provisional application No. 62/544,451, filed on Aug. 11, 2017.

(51) Int. Cl. B06B 1/02; B81B 3/00; B81C 1/00; G01N 29/24

(52) U.S. Cl. CPC B06B 1/0292; B81B 3/0083; B81C 1/00714; G01N 29/2406; G01N 2291/106; B81B 2203/0315; B81B 2203/04; B81C 2203/031; B81C 2203/032; B81B 2201/0271

(57) ABSTRACT

A substantially optically-transparent capacitive micromachined ultrasonic transducer (CMUT) and methods of fabricating the same are disclosed herein. In one implementation, the CMUT comprises a substantially optically-transparent substrate having a cavity; a substantially optically-transparent patterned conductive bottom electrode situated within the cavity of the substrate; and a substantially optically-transparent vibrating plate comprising at least a conducting layer, wherein the vibrating plate is bonded to the substrate. In some implementations the substantially optically-transparent CMUT can be embedded in a display glass of, for example, a television set, a computer monitor, a tablet, mobile phones, smartwatches, and the like.

### CROSS-REFERENCE TO RELATED APPLICATION

This application claims priority to and benefit of U.S. provisional patent application Ser. No. 62/544,451, filed Aug. 11, 2017, which is fully incorporated by reference and made a part hereof.

### GOVERNMENT SUPPORT CLAUSE

This invention was made with government support under grant number D13AP00043 awarded by the Department of Defense/Defense Advanced Research Projects Agency (DOD/DARPA); grant number HL117740 awarded by the National Institutes of Health (NIH); and grant number 1160483 awarded by the National Science Foundation (NSF). The government has certain rights to this invention.

### BACKGROUND

Capacitive micromachined ultrasonic transducers (CMUTs) have become an attractive candidate for next-generation ultrasonic imaging and therapy systems. The basic building block of a CMUT is a capacitor cell with a fixed bottom electrode and a moveable top electrode in the form of a thin plate, which can be put into vibration by electrostatic actuation. When an ultrasound wave impinges on the plate, the capacitance of the structure is modulated, which in turn generates a current when there is a constant voltage bias across the capacitor. The dimensions and the material of the plate determine the operating frequency.

The combination of ultrasonics and optics is desired in many applications such as integrating ultrasound sensing with flat panel displays, embedded optical vibrometry, and photoacoustic imaging. Currently, we spend a significant amount of our time looking at an electronic display, i.e., a computer, a smartphone, a tablet, or a TV. Our direct interaction with these displays is mostly based on receiving the visual/audio information and in some cases providing input using gesture or a touch sensor integrated with the display. For audio interaction there is a separate microphone and loudspeakers on these devices. For authentication, there are fingerprint scanners based on capacitive, optical, or ultrasonic sensors. Touch sensor seems to be the only standard sensor device closely integrated with the display. Direct integration of other sensors and physical interfaces with electronic displays is desired for scaling the systems employing these displays as well as for enhancing the way we interact with the electronic devices around us.

The opacity of materials used in conventional piezoelectric transducer constructs has severely restricted such applications. For example, lithium niobate with indium tin oxide (ITO) electrodes has been investigated to build a transparent piezoelectric transducer. However, transparent CMUTs are desired because of the benefits such as ease of fabrication and integration, and broad bandwidth for applications such as high quality sound directional sound.

Therefore, a CMUT having improved optical transparency in the visible to near-infrared (NIR) wavelength regime and methods of fabricating same are therefore desired to fill this gap.

### SUMMARY

Disclosed herein is a fabrication method for capacitive micromachined ultrasonic transducer (CMUT) arrays with improved optical transparency in the visible to near-infrared (NIR) wavelength regime. An enabler of embodiments of the presented invention is the use of a substantially optically-transparent material (e.g., glass) as a substrate and conductive transparent material (e.g., indium-tin-oxide (ITO)) for the electrodes, and if needed optically transparent bonding materials (e.g., BCB or SU-8). Embodiments of the described transparent ultrasonic transducer can be used for several different applications in the medical domain as well as for consumer use. A transparent ultrasonic array enables alignment of the optical and acoustic paths for photoacoustic imaging. The described device can be set up as a biosensor with optical readout. In the consumer space, embodiments of the described invention enable realization of acoustic and ultrasonic transducers embedded in the cover glass of display devices used in television sets, computer monitors, kiosks, tablets, mobile phones, smartwatches, etc. as well as other glass surfaces. Such transducers can be used for gesture recognition, air-coupled imaging, generating audible sound (directional and omnidirectional), fingerprint scanning, to capture sound (as a wideband microphone), a touch sensor, and the like.

Other systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF THE DRAWINGS

The following detailed description will be better understood when read in conjunction with the appended drawings, in which there is shown one or more of the multiple embodiments of the present disclosure. It should be understood, however, that the various embodiments of the present disclosure are not limited to the precise arrangements and instrumentalities shown in the drawings.

FIGS. 1A-1G illustrate an exemplary fabrication process for a transparent CMUT.

FIG. 2 is optical and atomic-force microscopy (AFM) images of the exemplary transparent CMUT of FIG. 1 showing the indium-tin-oxide (ITO) electrode in the etched glass cavities.

FIG. 3 is an optical image of an exemplary finished CMUT element with ITO bottom electrode and circular cells with a diameter of approximately 78 μm and a silicon plate thickness of approximately 2.5 μm.

FIG. 4A shows six CMUT elements with ITO bottom electrodes, which illustrates the improved transparency of the bottom electrodes, while FIG. 4B shows six CMUT elements with Cr/Au bottom electrodes presented for comparison.

FIGS. 5A and 5B are graphs showing optical transmission measurements where FIG. 5A shows transmission of the bottom electrodes on approximately 700 μm thick glass substrate (Borofloat33) and FIG. 5B shows transmission of the final exemplary devices.

FIGS. 6A and 6B are graphs showing measured electrical input impedance of the exemplary fabricated device (VDC=30 V) where FIG. 6A shows the real part and FIG. 6B shows the imaginary part.

FIG. 7 is a 3-D drawing showing the different layers in an exemplary substantially transparent CMUT device.

FIG. 8 is a schematic diagram of an exemplary CMUT with improved transparency with backside illumination for photoacoustic imaging.

FIGS. 9A-9E illustrate a fabrication process flow for the exemplary CMUT of FIG. 8 comprising (FIG. 9A) annealed ITO bottom electrode in glass cavities; (FIG. 9B) anodic bonding and handle/BOX layer removal; (FIG. 9C) silicon etch; (FIG. 9D) PECVD silicon nitride deposition; and (FIG. 9E) silicon nitride etch, evaporate and lift off metal pads.

FIGS. 10A and 10B illustrate electrical input impedance measurements (Vdc=18 V) for the exemplary CMUT of FIG. 8 where FIG. 10A illustrates the real part and FIG. 10B illustrates the imaginary part.

FIG. 11A shows an optical picture of a CMUT die with 6 exemplary CMUT elements on a “NC STATE UNIVERSITY” logo (left) and an optical picture of an exemplary CMUT element (right), while FIG. 11B shows optical transmittance characteristics of the CMUT die of FIG. 11A.

FIGS. 12A and 12B show pulse-echo measurement where FIG. 12A illustrates an echo signal; and FIG. 12B illustrates a Fourier transform of the echo signal.

FIG. 13A is an exemplary diagram of an experimental setup (inset graph shows the CMUT mounted on the PCB with a cutout to allow illumination); FIG. 13B is a bottom view of the PCB with CMUT (inset graph indicates the relative location of the laser output and CMUT elements); and FIG. 13C is a side view of PCB attached on the holder with the optical fiber bundle in the back.

FIGS. 14A-14C illustrate pencil lead, made of graphite, cross-sectional photoacoustic (PA) imaging results where FIG. 14A illustrates a sample A-scan at X=0 mm and its Fourier transform after applying a Gaussian window; FIG. 14B illustrates signal paths of the four signals on the A-scan; and FIG. 14C illustrates a reconstructed image.

FIG. 15A illustrates a received PA signal using 1-mJ laser power at 12-mm travel distance: one-way pencil lead signal (PA_{target}) and two-way silicon plate signal (PA_{cmut}); FIG. 15B illustrates equivalent electrical excitation amplitude for 1 mJ laser excitation.

FIGS. 16A and 16B are images of ICG tube phantom where FIG. 16A is a photograph of the ICG-filled polyethylene tube and FIG. 16B is a 3D rendered image of the ICG-filled polyethylene tube.

FIG. 17 shows a transparent parametric ultrasonic array embedded in display glass can be used to generate directed beams in different directions to create sound spots by nonlinear demodulation.

FIG. 18 shows an example of the layers that comprise a typical flat-panel display.

FIG. 19A is an image of a silicon-based parametric CMUT array (not transparent) on a 100-mm wafer; FIG. 19B illustrates measured beam patterns for primary frequencies and the difference frequency compared to diffraction at 5 kHz for the CMUT array of FIG. 19A; and FIG. 19C illustrates measured sound pressure levels for primary frequencies and the difference frequency in audible range for the CMUT array of FIG. 19A.

FIGS. 20A-20E illustrate an optically transparent air-coupled capacitive micromachined ultrasonic transducer (CMUT) fabricated using adhesive bonding where the exemplary completed wafer (single CMUT element) was placed on a “NC State University” logo to show the transparency (FIG. 20B); the average optical transmission of the device is measured as ˜70% in the 400-1000-nm wavelength range (FIG. 20C); and the electrical input impedance was measured in air (FIG. 20D (real) and FIG. 20E (imaginary)).

FIGS. 21-24 illustrate additional alternative processes and material for fabrication of a substantially transparent CMUT using adhesive bonding.

FIGS. 25-27 illustrate additional alternative processes and material for fabrication of a substantially transparent CMUT using anodic bonding.

FIG. 28 illustrates an exemplary cavity profile for a CMUT fabricated according to the processes described in FIGS. 21-27.

FIG. 29 is a graph that illustrates atmospheric deflection for a CMUT fabricated according to the processes described in FIGS. 21-27.

FIG. 30 is an image of a CMUT wafer created using the SU-8 bonding process.

FIG. 31 is an image of a CMUT wafer created using the BCB bonding process.

FIG. 32 is a graph that illustrates CMUT transmittance with the SU-8 process.

FIG. 33 is a graph that illustrates CMUT transmittance with the BCB process.

FIG. 34 illustrates an annular array with three concentric CMUT rings.

FIG. 35 illustrates an exemplary spiral CMUT element.

FIG. 36 illustrates a static deflection profile of a spiral CMUT design.

FIG. 37 is a graph illustrating simulated displacement spectrum showing 17% fractional bandwidth for the exemplary spiral CMUT.

### DETAILED DESCRIPTION

Before the present methods and systems are disclosed and described, it is to be understood that the methods and systems are not limited to specific synthetic methods, specific components, or to particular compositions. It is also to be understood that the terminology used herein is for the purpose of describing particular embodiments only and is not intended to be limiting.

As used in the specification and the appended claims, the singular forms “a,” “an” and “the” include plural referents unless the context clearly dictates otherwise. Ranges may be expressed herein as from “about” one particular value, and/or to “about” another particular value. When such a range is expressed, another embodiment includes¬ from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other additives, components, integers or steps. “Exemplary” means “an example of” and is not intended to convey an indication of a preferred or ideal embodiment. “Such as” is not used in a restrictive sense, but for explanatory purposes.

Disclosed are components that can be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all aspects of this application including, but not limited to, steps in disclosed methods. Thus, if there are a variety of additional steps that can be performed it is understood that each of these additional steps can be performed with any specific embodiment or combination of embodiments of the disclosed methods.

Disclosed and described herein are embodiments of a substantially optically-transparent capacitive micromachined ultrasonic transducer (CMUT) comprising a substrate having a cavity, wherein the substrate is comprised of substantially optically-transparent material; a patterned conductive bottom electrode situated within the cavity of the substrate, wherein the patterned conductive bottom electrode is comprised of substantially optically-transparent material; and a vibrating plate comprising at least a conducting layer, wherein the vibrating plate is bonded to the substrate and wherein the vibrating plate is at least partially comprised of substantially optically-transparent material.

In various embodiments, the substrate can be comprised of substantially optically-transparent material compatible with adhesive bonding such as, for example, glass, quartz, or fused silica. For example, the substrate may be comprised of borosilicate glass. The substantially optically-transparent material used to form the substrate may also comprise flexible transparent materials.

Though not required, in some instances an air-tight seal is formed between the substrate and the vibrating plate.

The bottom conductive electrodes are insulated from the conducting layer of the vibrating plate. For example, in some instances spacers are formed in the substrate to form an insulating space between the patterned conductive bottom electrode and the conducting layer of the vibrating plate. In other instances, a substantially optically-transparent insulating layer is situated substantially between the patterned conductive bottom electrode and the conducting layer of the vibrating plate. In some instances, the insulating layer is attached to the bottom of the conducting layer of the vibrating plate. In other instances, the insulating layer can be on top of the patterned conductive bottom electrode. Regardless of where situated, the insulating layer comprises a high dielectric constant material. For example, the insulating layer may comprise silicon nitride, Hafnium (IV) oxide, or even an adhesive material used for bonding. As non-limiting examples, the adhesive material used for bonding may comprise BCB or SU-8.

The vibrating plate of the CMUT further comprises a conductive electrode. In various instances, the vibrating plate conductive electrode is situated on a top side of the vibrating plate. In other instances, the vibrating plate conductive electrode is situated on a bottom side of the vibrating plate.

The conducting layer of the vibrating plate can be comprised of any substantially optically-transparent conductive material including, for example, ITO. In some instances, the vibrating plate is comprised of substantially transparent insulating material such as silicon, silicon nitride or glass. When the vibrating plate is comprised of an insulating material, an optically transparent conducting material is added to the plate structure to form the top electrode of the CMUT.

In some instances, as shown herein, the substrate of the CMUT comprises a plurality of cavities, each cavity having a patterned conductive bottom electrode. One or more of the cavities may be vacuum sealed. For immersion applications including medical imaging vacuum sealing may be desired, but for air coupled applications air could be left in the cavity with perforated holes to let the air move in and out to control the bandwidth of the transducer.

In some instances, the patterned conductive bottom electrodes of the plurality of cavities are electrically connected to one another.

Some embodiments of the disclosed CMUT comprise one or more conductive vias through the substrate, wherein the one or more vias are used to electrically connect with at least one of the patterned conductive bottom electrodes, the conductive layer of the vibrating plate, or a conductive electrode of the vibrating plate.

The patterned conductive bottom electrode is generally comprised of a conductive material that is substantially optically-transparent, such as indium-tin-oxide (ITO) or other conductive transparent or substantially-transparent materials.

In various instances, the vibrating plate can be anodically bonded to the substrate, while in other instances, the vibrating plate is adhesively bonded to the substrate. For example, the vibrating plate can be adhesively bonded to the glass substrate using a polymer. The polymer may comprise a substantially optically-transparent photoresist such as photosensitive BCB, SU-8, PermiNex™, and the like. In other instances, the polymer comprises a substantially optically-transparent non-photosensitive polymer such as dry-etch BCB and the like.

In various aspects, the embodiments of the disclosed CMUT can be operated in a conventional, collapse-snapback mode, an array operation, or a collapse mode.

Applications of the disclosed embodiments include embedding the CMUT into a glass display. In some instances, the glass display may comprise a portion of the CMUT. For example, the glass display may comprise all or a portion of the substrate of the CMUT. In various implementations the CMUT is embedded in the cover glass of display devices used in television sets, computer monitors, tablets, mobile phones, smartwatches, and the like and can be used in one or more of ultrasound imaging, ultrasound therapy, ultrasound-based sensing, chemical gas sensors, photoacoustic imaging transducers, biosensors, directional sound source embedded in a display glass, fingerprint scanner embedded in display glass, touch sensor with force sensing in display glass, wideband microphone embedded in display glass, gesture recognition interface embedded in display glass, and the like.

The present methods and systems may be understood more readily by reference to the following detailed description of preferred embodiments and the Examples included therein and to the Figures and their previous and following description.

Disclosed herein are embodiments of a CMUT with improved transparency on a substantially optically-transparent substrate (e.g., borosilicate glass) using a substantially optically-transparent conductive material (e.g., ITO) as the bottom electrode. In one implementation the top electrode is a doped silicon plate (˜2-um thick) formed by anodic bonding, which is also the main light absorbing layer in the current device material stack. This transducer is shown to provide improved optical transparency and to be acoustically functional. Other embodiments comprise fabrication process flows that further improve the transparency by replacing the silicon plate with other materials such as glass and using other bonding techniques such as adhesive bonding.

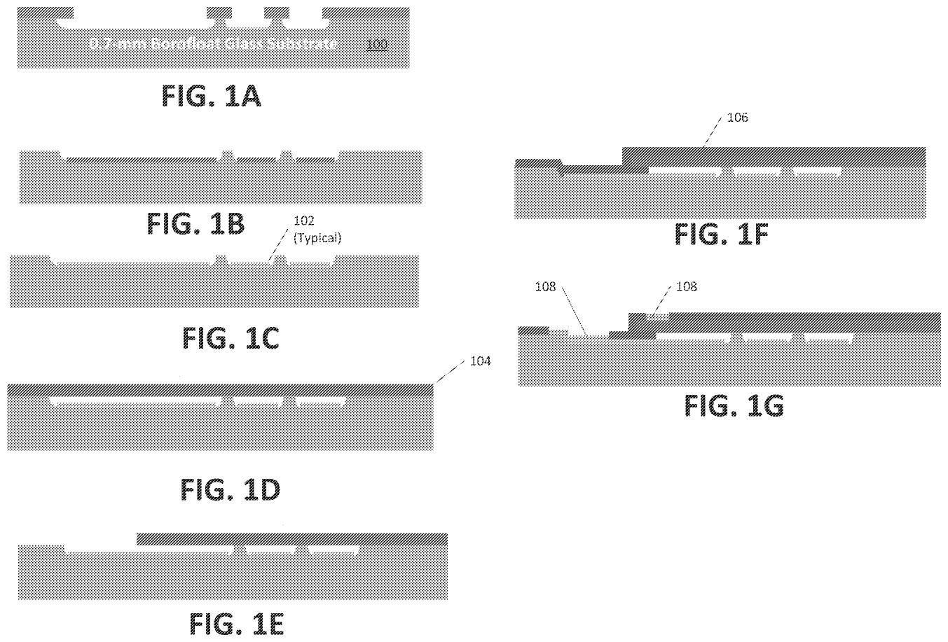

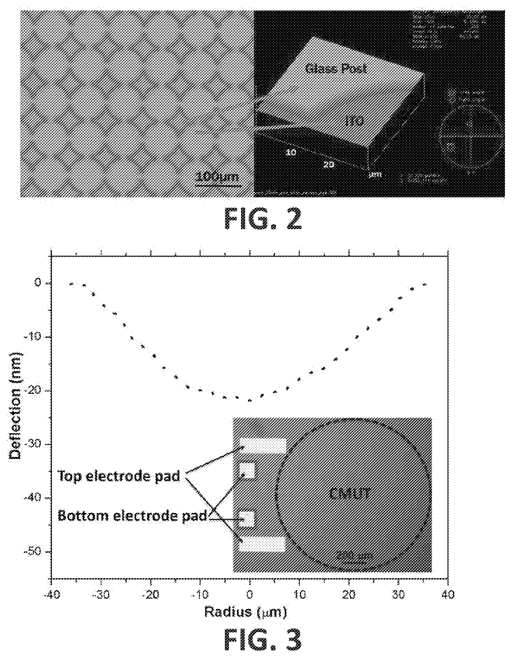

FIGS. 1A-1G illustrate an exemplary fabrication process for one of the embodiments of a transparent CMUT. The exemplary fabrication process starts with an approximately 0.7-mm-thick, 100-mm diameter borosilicate glass wafer (Borofloat33, Schott A G, Jena, Germany) 100 that has a RMS surface roughness of approximately 0.7 nm, a warp less than approximately 0.05% (<10 μm), and bow <58 μm). As shown in FIG. 1A, the cavities are patterned using an approximately 2-μm thick photoresist. The patterned wafer is hard-baked for approximately 10 minutes at an elevated temperature of approximately 125° C. to promote the adhesion between the substrate and the photoresist. The glass cavities are etched down to approximately 350 nm in 10:1 BOE solution in two cycles of a total of approximately 15 minutes. An interval hardbake at approximately 125° C. was performed between the etching cycles to avoid photoresist peeling off. The wet etch process had a lateral to vertical etch rate ratio of 10:1. Therefore an approximately 3.5-μm lateral undercut was achieved after the glass etching, which is beneficial for the later ITO lift-off step. The wafer was transferred into a RF sputtering system without removing the photoresist. An approximately 150-nm ITO film was sputtered over the wafer at room temperature and then the lift-off was done in heated N-Methyl-2-pyrrolidone (NMP@70° C.) solution (see FIG. 1B) to form electrodes 102. The optical and AFM images in FIG. 2 show the ITO electrode in the etched glass cavities. The RMS roughness was approximately 0.5 nm on the ITO surface and approximately 0.7 nm on the glass post. After this step, the wafer was annealed at approximately 450° C. for approximately 5 min in a rapid thermal annealing (RTA) system (see FIG. 1C). The ITO conductivity and transparency generally improves after annealing. The sheet resistance of the ITO bottom electrode 102 before annealing was approximately 300 Ω/sq, and reduced to approximately 20 Ω/sq after annealing. The ITO optical properties before and after annealing are discussed in greater detail herein. Though not shown in FIG. 1, an alternative interconnection method used for CMUT arrays is to use a glass substrate with through-glass via (TGV) interconnects.

An SOI wafer device layer was used to form the CMUT top plate 104. In one of the embodiments, the device layer was n-type silicon with approximately 0.001 to 0.005 Ω·cm resistivity. The SOI device layer and the processed glass surface were bonded together at approximately 350° C. under approximately 2.5-kN down force and approximately 700-V bias voltage in vacuum. The handle wafer was ground down to approximately 100 μm. The top plate was released after removing the remaining handle layer using heated tetramethylammonium hydroxide solution (10% TMAH at 80° C.) and BOX layer using 10:1 BOE solution (see FIG. 1D). Then, the silicon plate 104 was etched on the pad locations to evacuate the trapped gas inside the cavities and to reach bottom electrodes 102 (see FIG. 1E). The device was re-sealed using approximately 1-μm conformal PECVD silicon nitride 106 (see FIG. 1F). Then, the sealing silicon nitride was etched in order to reach the top plate and bottom electrode for electrical contacts. The device was finished after evaporating and lifting off a stacked layer of approximately 20-nm chromium and approximately 180-nm gold to form the bond pads 108 (see FIG. 1G).

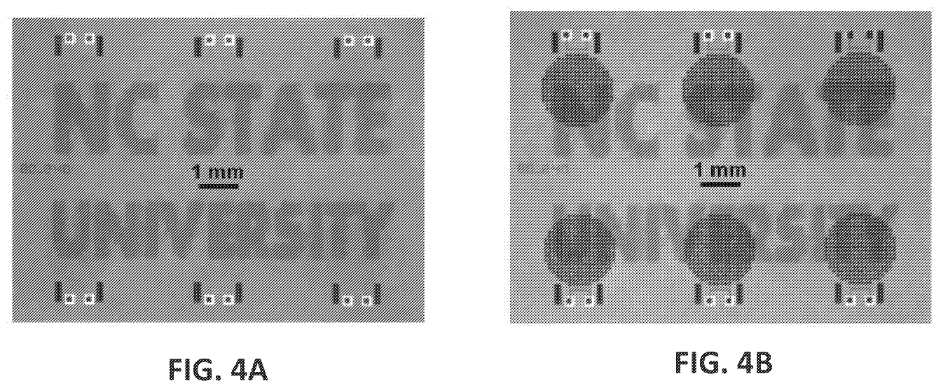

FIG. 3 shows the optical image of a finished CMUT element with ITO bottom electrode and circular cells with a diameter of approximately 78 μm and a plate thickness of approximately 2.5 μm. The atmospheric deflection measurement in the center of a cell confirmed the devices are vacuum-sealed.

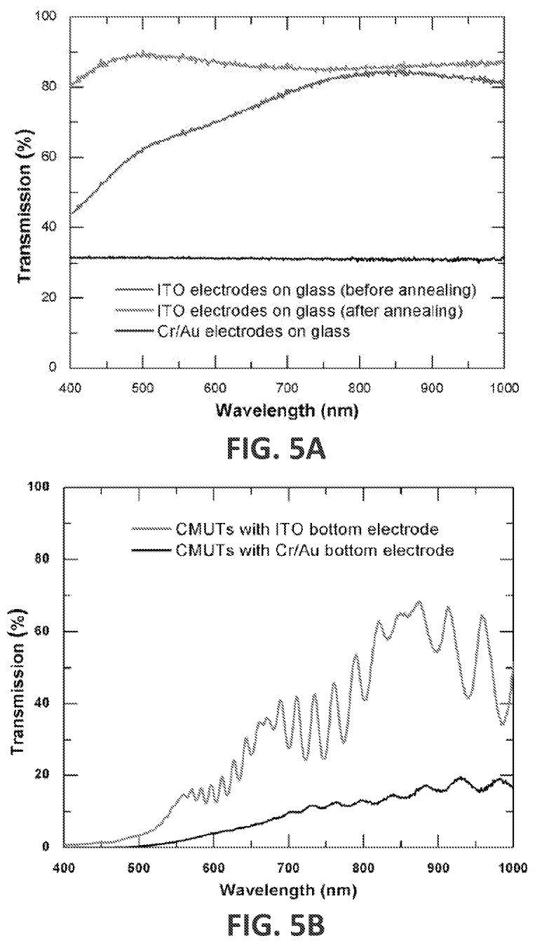

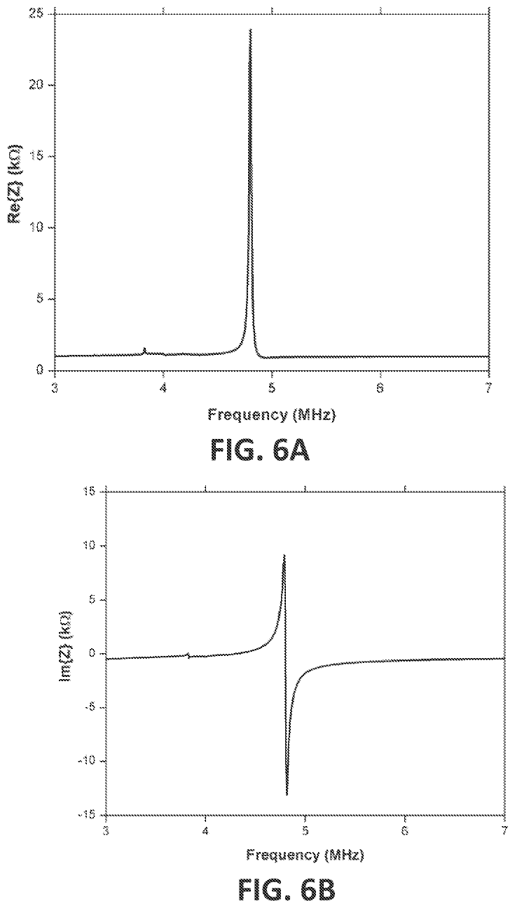

FIG. 4A shows the optical images of the CMUTs fabricated with ITO bottom electrodes under microscope with backside illumination. The die with six CMUT elements was placed above a “NC STATE UNIVERSITY” logo. In comparison, FIG. 4B shows the same setup with CMUTs fabricated with Cr/Au bottom electrodes, such as those described in U.S. patent application Ser. No. 15/225,118, filed Aug. 1, 2016, which is fully incorporated by reference. From the optical image, it is clear that the device with ITO bottom electrode (FIG. 4A) has a much-improved transparency in visible light range. To further characterize the transmission coefficient, the ITO and Cr/Au bottom electrodes and the finished devices were measured using a spectrophotometer (Cary 60 UV-Vis, Agilent Technologies, Santa Clara, Calif.) from 400 nm to 1000 nm wavelength range. FIG. 5A shows the transmission through the 150-nm ITO bottom electrode on glass before and after annealing, in comparison to 150-nm Cr/Au bottom electrode on glass. FIG. 5B shows the optical transmission through the final device with ITO bottom electrodes and Cr/Au electrodes. It is clear that the CMUTs with ITO bottom electrodes have a significant transmission improvement in the measured wavelength range. However, the 2-μm silicon plate is a challenge for the transmission in the shorter wavelength range.

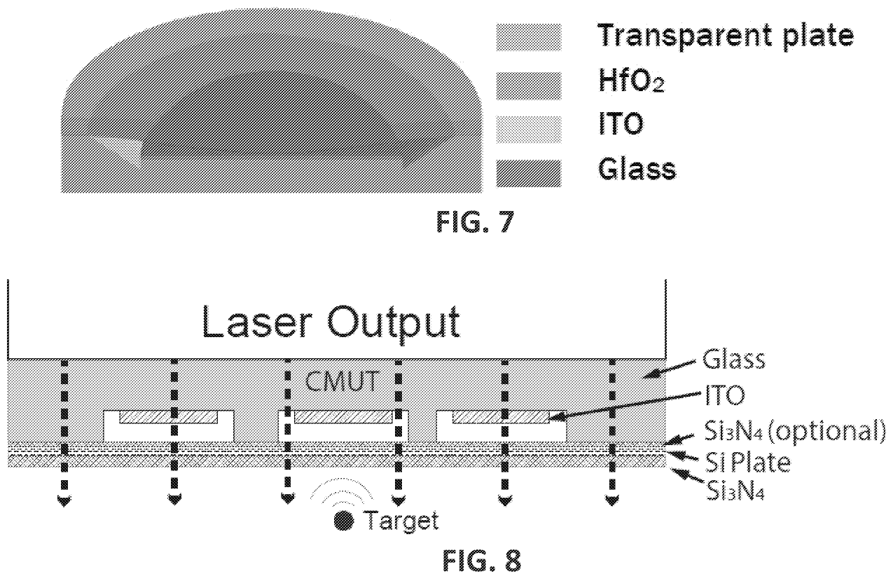

The electrical input impedance of a fabricated CMUT element was measured in air (FIGS. 6A and 6B). The CMUT showed 4.75-MHz resonant frequency at a DC voltage of 30 V (˜80% pull-in voltage). The series resistance of the fabricated device is ˜1 kΩ, which corresponds to the expected 50 squares for the bottom electrode. Using the thicker bottom electrodes or parallel connections to the pads could reduce the series resistance.

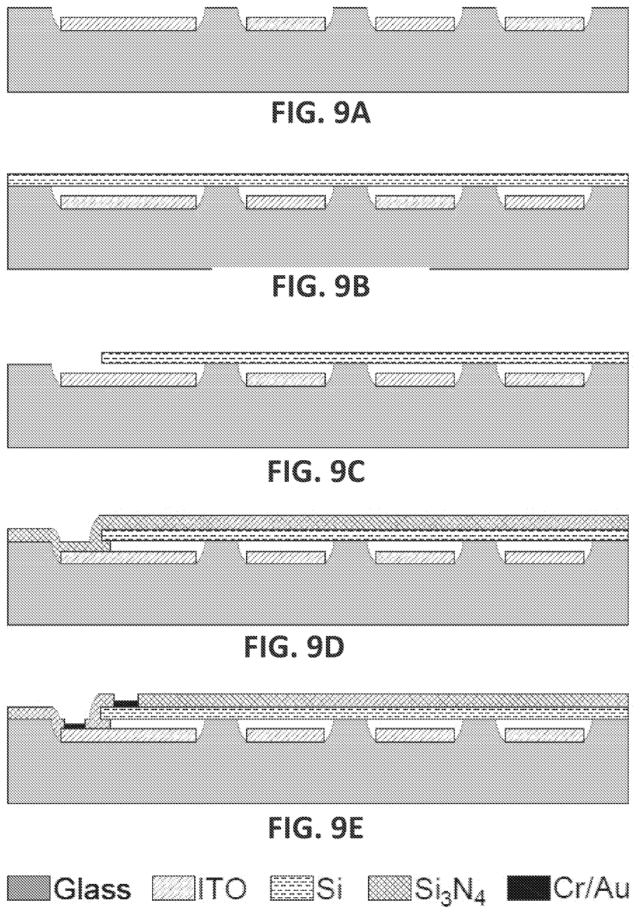

CMUTs fabricated with the Cr/Au bottom electrodes of 150-nm thickness (FIG. 4B) show <20% optical transmission. By using ITO as the bottom electrode instead of Cr/Au, the optical transmission through the device is improved to ˜50% in the wavelength range from 700 nm to 1000 nm. The low optical transmission in the lower wavelength regime is mainly caused by the absorption in the vibrating plate comprised of approximately 2-μm silicon. Alternative materials that can be used for the vibrating plate that can increase optical transmission include silicon nitride plate, ITO, and the like. Also, in one embodiment Hafnium (IV) oxide (HfO₂) can be used as an insulation layer between top and bottom electrodes, which could serve as a reliable high-k dielectric without adversely affecting the transparency. However, it is to be appreciated that other substantially transparent materials can be used as the insulation layer and/or the electrodes. Such an embodiment is illustrated in FIG. 7.

Below are descriptions of alternative embodiments of transparent CMUTs that can be used in various applications, some of which are described herein.

Photoacoustic Imaging (PAI): Recently, real-time array-based photoacoustic imaging systems have been implemented by retrofitting commercial ultrasound transducer arrays with optical fiber bundles with exit apertures formed as two narrow slits placed on each side of the ultrasound imaging array. One drawback of this approach is that the region right in front of the transducer is not efficiently illuminated. This is a more severe problem when the imaging field extends deep into the tissue. This approach also limits the footprint of the imaging probe as the fiber bundle and the closure required to place it next to the ultrasound array occupy extra space. This is a serious limitation for probes designed for intracavital use such as intravascular ultrasound probes or endoscopic and laparoscopic probes. With an ultrasound transducer array with improved optical transparency in the visible to near-infrared wavelength regime such as the embodiments described herein, a uniform beam can provide the optical illumination directly through the array. By this approach the near field of the transducer can be efficiently illuminated without the need for peripheral optical fiber bundles. Since the transducer will be built using materials with high optical transparency in the target wavelength range, spurious absorption in the transducer will also be minimized.

CMUT technology has the advantages of fabricating large arrays, integration with electronics, wide bandwidth, and broad selection of processing materials. CMUT is especially suitable for PAI due to the broadband nature of the photoacoustic signal (typically tens of MHz). A challenge in PAI is the arrangement of the laser source and the ultrasound transducer. Various approaches have been demonstrated for different applications. One of the commonly used arrangement is to have the light source illuminate the target from the single side or two sides at a right angle to the acoustic path. Another implementation is to have the light source integrated as two fiber bundles along the length direction of a 1D transducer array. However, this method does not illuminate the surface area under the transducer array and results in a blind spot in front of the transducer. Also, it is difficult to use this approach with 2D arrays, which would result in larger area under the 2D transducer array not being illuminated. This approach also limits the footprint of the imaging probe as the fiber bundle and the closure required to place it next to the ultrasound array occupy extra space. The small footprint is especially desirable for intracavital probes. The light illumination has also been distributed using a spherical mirror. Another approach is face-to-face arrangement which is also referred to as forward-mode, which is not practical for many clinical applications.

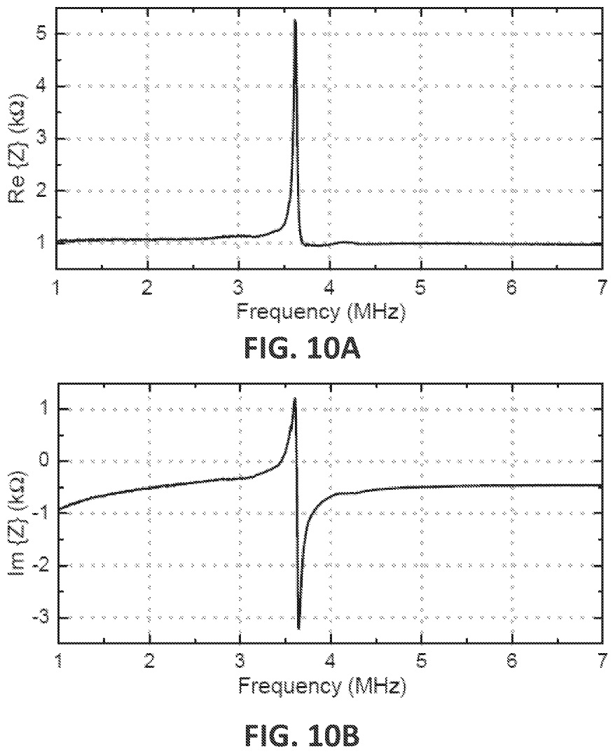

A CMUT for PAI is shown in FIG. 8. This embodiment of a CMUT is fabricated on a glass substrate with ITO bottom electrodes. A 1.5-μm silicon layer was formed by anodic bonding over the glass cavities with a 1-μm silicon nitride passivation layer on top. One or more optional insulation layers (Si₃N₄) can be incorporated in the device structure to prevent an electrical short circuit in case the Si plate pulls in. When used in conventional mode receive-only operation the insulating layer can be omitted. As shown in FIG. 8, the laser output is fixed at the back of the CMUT so that the light passes through the device and illuminates the target to generate photoacoustic signals which can be detected by the CMUT.

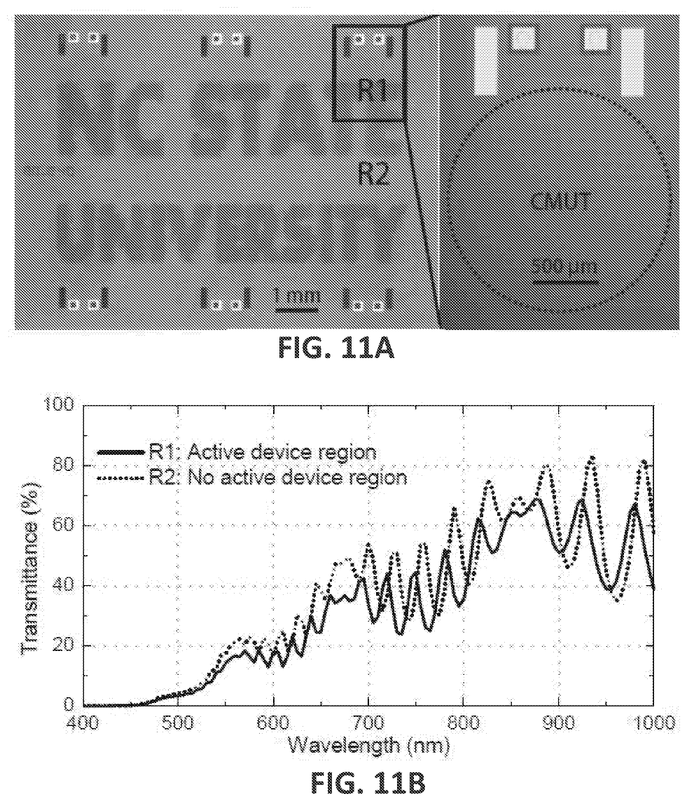

In a similar process as was described in relation to FIGS. 1A-1G, above, FIGS. 9A-9E illustrate the fabrication process for a CMUT for PAI. The starting substrate was a standard 0.5-mm thick, 100-mm diameter borosilicate glass wafer (Borofloat™ 33, Schott A G, Jena, Germany) that has a high surface quality with an RMS roughness of 0.7 nm and a good flatness (warp <10 μm and bow <58 μm). The cavities were patterned using a 2-μm-thick photoresist and then etched down to 350-nm depth in 10:1 buffered oxide etchant (BOE) in two cycles for a total time of 15 minutes. The wafer was baked at 125° C. between the wet etching cycles to prevent photoresist from peeling off. The BOE etching process has a lateral-to-vertical etch rate ratio of 10:1. Therefore a 3.5-μm undercut can be achieved during the cavity formation, which is beneficial for the later ITO lift-off step. The wafer was then transferred into a RF sputtering system without removing the photoresist. An ITO film with a thickness of 170 nm was sputtered over the wafer in ambient temperature and then lifted off in a heated N-Methyl-2-pyrrolidone (NMP@70C) solution. Then the wafer was annealed at 450° C. for 5 minutes in a rapid thermal annealing (RTA) system to improve the ITO conductivity and transparency. The SOI device layer was a 2±0.5-μm-thick, n-type single-crystal silicon with 0.001-0.005 Ω·cm resistivity. The SOI wafer and the processed glass surface were bonded together by anodic bonding at 450 C under 2.5-kN force and 700-V bias voltage in vacuum. The top plate was formed after the handle wafer and BOX layer removal.

The silicon plate was etched at the bottom pad location to evacuate the gas generated during anodic bonding. The device was sealed using a 1-μm conformal PECVD silicon nitride. The sealing nitride was etched to reach the conductive top plate silicon and the bottom electrode to form electrical contacts. The device fabrication was completed after evaporating and lifting off a stacked layer of 20-nm chromium and 180-nm gold as the bond pads. Though not shown in FIG. 9, an alternative interconnection method used for CMUT arrays is to use a glass substrate with through-glass via (TGV) interconnects. The physical dimensions of the fabricated device are summarized in Table I.

TABLE I
PHYSICAL PARAMETERS OF THE FABRICATED CMUT

| Shape of the cell | Circular |
|---|---|
| Number of cells per element | 483 |
| Cell diameter, μm | 82 |
| Cell-to-cell distance, μm | 4 |
| Element radius, mm | 1 |
| Silicon middle layer thickness, μm | 1 |
| Silicon layer thickness in plate, μm | 1.5 |
| Vacuum gap height, μm | 0.18 |
| Bottom ITO thickness, μm | 0.17 |
| Glass substrate thickness, μm | 500 |

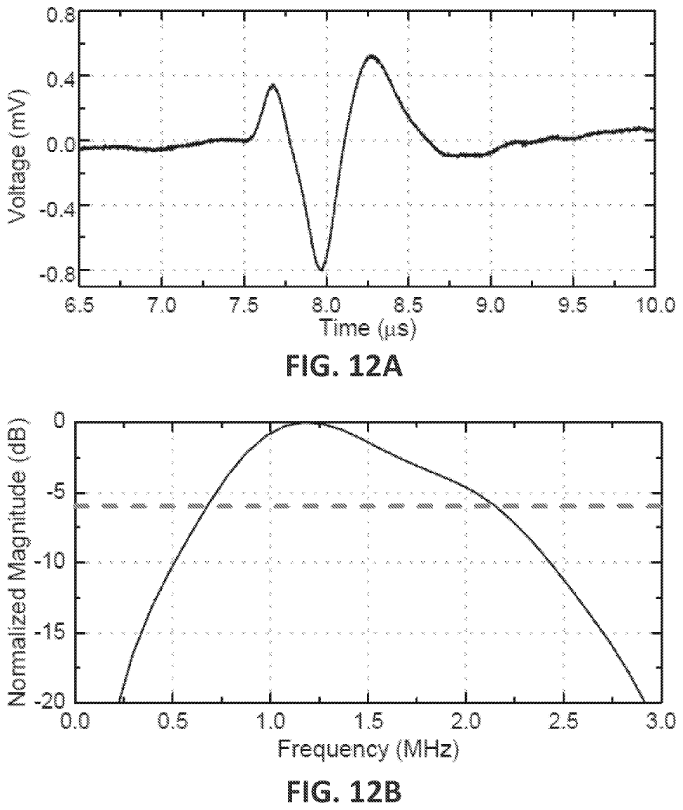

The real and imaginary parts of the electrical input impedance of the fabricated CMUT was measured in air using a network analyzer (Model E5061B, Agilent Technologies, Inc., Santa Clara, Calif.) (FIGS. 10A and 10B). The open circuit resonance frequency of the CMUT element was measured as 3.62 MHz at 18-V dc voltage, which is approximately 75% of the pull-in voltage. The 1-k baseline in the real part corresponds to the series resistance of the device, which is mainly contributed by the resistance of the patterned ITO bottom electrode. This resistance could be reduced by depositing a thicker ITO, layer or using parallel connections to the pads which is contemplated in the embodiments described herein. For the PAI experiment described below, two connections to two pads reaching the ITO bottom electrode were wire bonded together to reduce the series resistance.

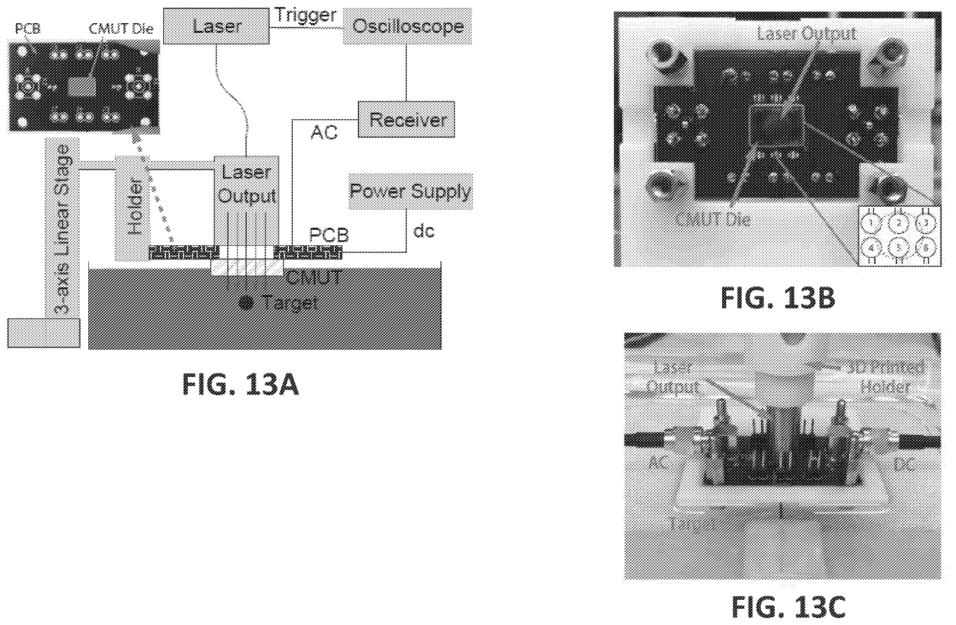

FIG. 11A shows the optical image of exemplary fabricated CMUTs. On the left of FIG. 11A is a CMUT die with six CMUT elements placed on a “NC STATE UNIVERSITY” logo under microscope with backside illumination. It can be seen that the device has a good transparency in visible light range. The metal pads indicate the location of each element. The right side of FIG. 11A is a close-up image of a single CMUT element. Optical transmission was measured using a spectrophotometer (Cary 60 UV-Vis, Agilent Technologies, Santa Clara, Calif.) in the wavelength range from 400 nm to 1000 nm. The light source was focused through a converging lens to achieve a focal area of a 150 μm×150 μm square. On the CMUT die, the region was measured where the active CMUT cells are (R1) and also where there are no CMUT cells (R2). The measured results indicates the 1.5-μm silicon plate is the challenge for transmission (FIG. 11B) while the ITO bottom electrode has little effect on the optical transmission. This result also justifies illumination through the whole die in the photoacoustic imaging experiment.

Although this embodiment of the presented transducer is designed primarily as a receiver for photoacoustic imaging, a pulse-echo measurement was performed in vegetable oil to characterize the small-signal bandwidth in immersion and also to help quantify the effects of optical absorption in the silicon plate on the generation of spurious transmit signals, which is described below.

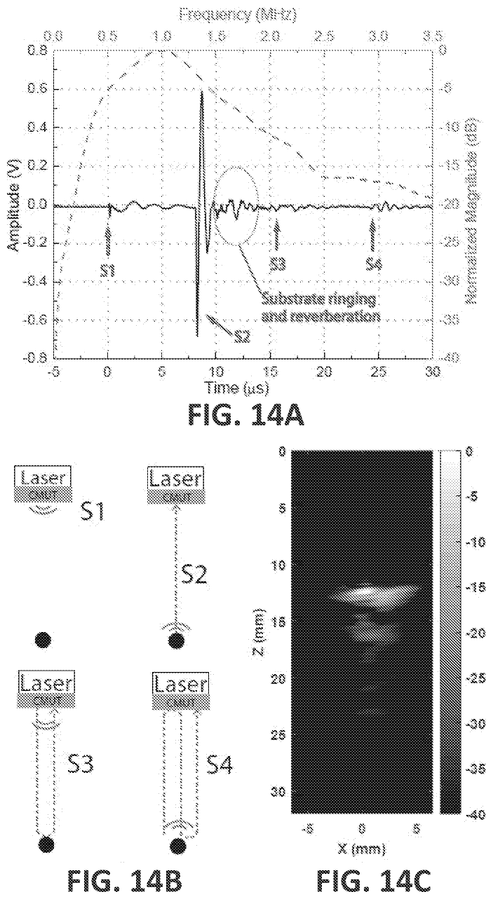

The CMUT was placed 1.2 cm away from a plane reflector and was biased at 18-V dc voltage (75% Vₚᵤₗₗ₋ᵢₙ). A 1-Vₚₚ, 250-ns pulse was used to excite the device. The received echo signal and its Fourier transform are shown in FIGS. 12A and 12B. The center frequency of the CMUT is 1.4 MHz with a 6-dB fractional bandwidth of 105%.

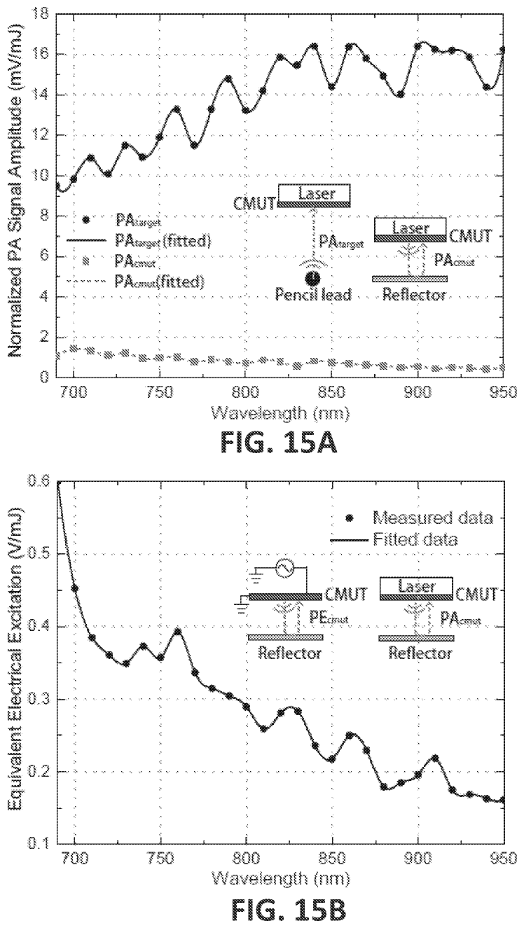

The diagram of the experimental setup for photoacoustic imaging is shown in FIG. 13A. The CMUT die was mounted on a printed circuit board (PCB) that has a bias-T circuit and switches to select individual CMUT elements for testing. The PCB was designed with a rectangular cutout in the center to allow light to pass through the CMUT die, as shown in the inset of FIG. 13A. After wire bonding, the CMUT and the laser output were fixed using a 3D-printed holder and mounted on a 3-axis linear stage (model PRO165, Aerotech Inc., Pittsburgh, Pa., USA) to enable mechanical scanning. The 3D-printed holder was used to ensure the relative position of the CMUT and the laser output does not change during the experiment. A dc power supply (model E3631A, Agilent Technologies, Santa Clara, Calif.) was connected to the PCB and the signal received by the CMUT was filtered and amplified by a receiver (model 5072PR, Olympus Corporation, Tokyo, Japan). The filtered and amplified signal was recorded by a PC-controlled digitizer (model NI PCI-5124, National Instruments, Austin, Tex.). The excitation laser source is a fiber-coupled optical parametric oscillator (OPO) pumped by a Q-Switched Nd:YAG laser (model Phocus Mobile, Opotek Inc., Carlsbad, Calif.) with a wavelength range from 690 nm to 950 nm. The laser pulses had a pulse-width of 4.5 ns and a repetition rate of 20 Hz. The output energy of the laser was calibrated using a pyroelectric energy detector (model: QE25, Gentec Inc., Quebec City, Canada). The output of the laser was coupled to the backside of the CMUT die using a fiber bundle with a diameter of 5 mm. The target and the coupling medium were placed in a glass container under the PCB. The bottom view of the PCB is shown in FIG. 13B with the inset graph indicating the relative location of the laser beam and the CMUT elements. The number 2 CMUT element was chosen on the die because the light illuminated through this entire device. The side view of fiber bundle, PCB, and the holder is shown in FIG. 13C.

Two different targets were imaged. The first imaging target was a 0.7-mm diameter pencil lead. The pencil lead was suspended 2 cm above the bottom surface of the glass container as shown in FIG. 13C. Vegetable oil was used as the medium instead of water as the transducer surface and bond wires were not electrically insulated. Vegetable oil was filled to approximately 1.5 cm above the pencil lead. Then the holder was lowered until the CMUT surface touched the oil. The laser beam output from the fiber bundle into the CMUT chip had wavelength of 830 nm and a fluence of 12 mJ/cm².

The CMUT was biased at 18-V dc voltage. Receiver gain was set at 20 dB and the cutoff frequency of the lowpass filter at 10 MHz. The transducer was scanned across the pencil lead and the received signals at each location was sampled at a rate of 200 MSa/s, digitized, and averaged 16 times to improve the SNR before recording.

The second target was designed to better mimic the condition of biological tissues. A polyethylene tube with inner diameter of 2.3 mm and outer diameter of 3.6 mm was looped and filled it with an indocyanine green (ICG) solution (50-μM), which is commonly used as a contrast enhancement agent in PAI. The tube was then suspended using fishing lines inside the glass container. Then the container was filled with a mixed solution of 1% Agar and 1% Intralipid (20% intravenous fat emulsion) in DI water to build the photoacoustic imaging phantom. After the phantom was solidified, a 5-mm oil layer was added on top of the solid phantom for acoustic coupling. The CMUT was again biased at 18-V dc voltage. This time the received signals were amplified with 40-dB gain. The laser wavelength was chosen as 790 nm to match the maximum absorption of the ICG solution. In order to get a stronger PA signal, this time a laser output fluence of 20 mJ/cm² was used into the CMUT chip. By mechanically scanning in x and y directions, volumetric data was recorded at a sampling rate of 200 MSa/s and by averaging of each scan line 16 times.

Photoacoustic images were reconstructed using the standard delay-and-sum (DAS) beamforming algorithms along with a coherence factor (CF) weighting. Prior to image reconstruction, every A-scan S(t) was processed as in:

$${S}_{processed} ( t ) = S ( t ) - t \frac{\partial S ( t )}{\partial t} \qquad ( 1 )$$

which can be written in its discrete form as:

S_{processes}(i)=S(i)−i(S(i)−S(i−1)) (2)

This preprocessing suppresses the low-frequency component in the signal. Then, the A-scans were filtered by a 0.15-MHz-4.5-MHz bandpass filter to eliminate out-of-band noise. After that, DAS receive-only beamforming was applied to form the PA image. Considering the radiation pattern of the CMUT and to maximize the image SNR, a threshold value of 14° was chosen and the contribution from an element was not taken into consideration if the angle from its normal to the pixel location was larger than the threshold. Finally, envelope detection was performed, and the image was multiplied by the coherence factor map. Logarithmic compression was performed before displaying the PA image.

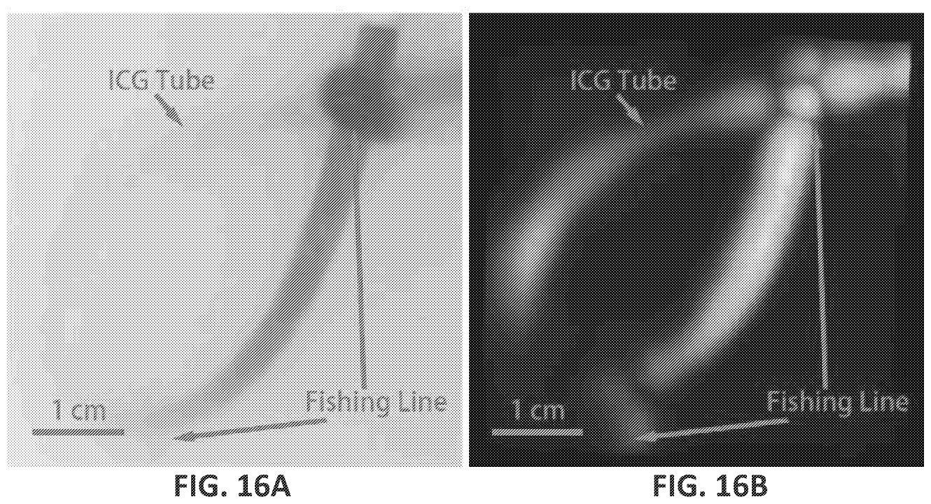

The experimental results of imaging of the pencil lead in oil are shown in FIGS. 14A-14C. A sample A-scan at X=0 mm is shown in FIG. 14A. Four signals (S1, S2, S3, S4) are marked on the A-scan with the signal paths shown in FIG. 14B. As the 4.5-ns wide laser pulse shines through the CMUT, some of the optical energy is absorbed in the silicon plate and converted to heat. Thermoelastic expansion of the silicon plate caused by rapid heating and cooling will set the plate into vibration at its natural frequency in oil, which results in the S1 on the A-scan. S2 is the received PA signal generated by the pencil lead. The tail signal after S2 is because of the substrate ringing of the device and the reverberations in the pencil lead. S3 is the pulse-echo signal transmitted due to S1, and reflected by the pencil lead, and therefore occurred at double the distance compared to S2. S4 is the PA signal generated by the pencil lead reflected by the silicon plate, and then reflected back by the pencil lead. Therefore, it appeared at three times the target depth.

The reconstructed B-scan image of the cross section of the pencil lead is shown in FIG. 14C with 40-dB dynamic range. The pencil lead was seen at the depth of approximately 12 mm Substrate ringing and the reverberations in pencil lead can be observed after the main signal. At the distance of 24 mm, a weaker signal (34 dB lower than pencil lead) was detected, which is due to the pulse-echo signal generated by the silicon plate absorption and corresponds to S3 on the A-scan.

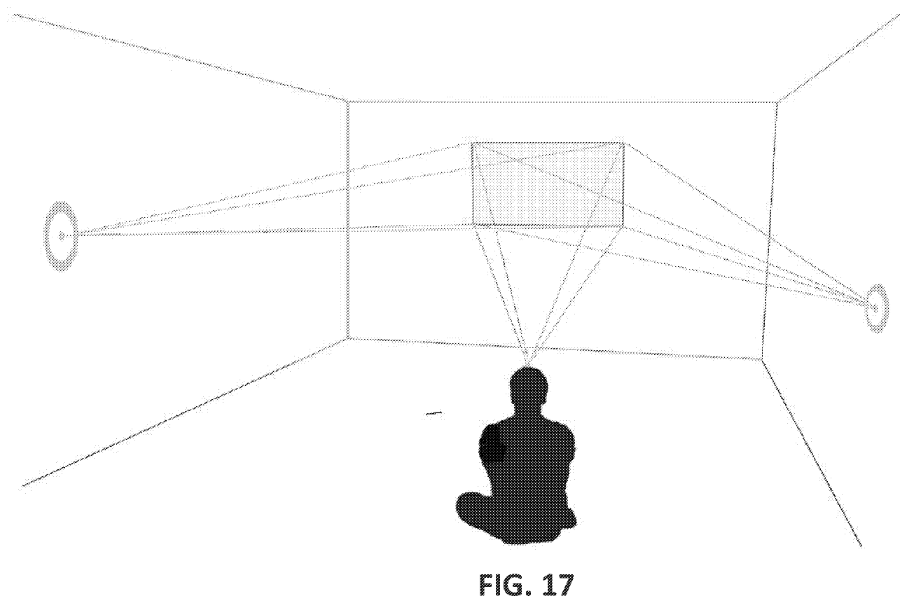

In order to further evaluate the effect of the silicon plate absorption, two experiments were performed. In the first experiment we compared the photoacoustic signals generated by the light absorption in the pencil lead (referred as PA_{target} in the following context) and the pulse-echo signals generated by photoacoustically induced vibration of the silicon plate (referred as PA_{cmut} in the following context) for the same travel distance in oil across the 690 nm to 950 nm wavelength range. PA_{target} was first recorded as described for the imaging experiments. To record PA_{cmut} also at 12-mm travel distance, the CMUT was placed 6-mm away from the glass container bottom, which served as a plane reflector without generating interfering PA signals. The laser wavelength was scanned from 690 nm to 950 nm wavelength range with a step of 10 nm. The received signals were normalized to 1-mJ laser energy through the CMUT. The results are plotted in (FIG. 15A) with curve fitting. It can be seen that for the same travel distance, PA_{cmut} is much smaller than PA_{target} (approximately 30 dB lower at wavelength of 830 nm).

In the second experiment, PA_{cmut} was compared to the pulse-echo signal generated by the electrical excitation (PE_{cmut}) for the same travel distance. The aim of this experiment is to find an equivalent excitation voltage for the transducer that would generate a PE_{cmut} equals to PA_{cmut}. A 250-ns, 1-V unipolar pulse was used to perform a regular pulse-echo measurement. The received echo signal amplitude was 1.5 mVₚₚ. Thus, the equivalent electrical excitation signal amplitude can be calculated for 1-mJ laser excitation through the CMUT (FIG. 15B). As an example, at the wavelength of 830 nm, the pulse-echo signal generated by photoacoustically induced vibration of the silicon plate using 1-mJ laser power is equivalent to that generated by the CMUT using 0.29-V electrical excitation.

One should also note that pencil lead, made of graphite, is both a strong absorber and a strong reflector. Therefore, the spurious transmit signal generated by photoacoustically induced vibration of the silicon plate (S2) is strongly reflected back and received by the CMUT. In PAI applications, the target is usually a strong absorber but not a strong reflector, such as human soft tissue or blood. In such a case, this signal will not be reflected and detected by the receiver. However, transmitted acoustic signal can still cause clutter issues in a photoacoustic image, especially as SNR degrades for issue at depth. Therefore, the further improvement of the device transparency is desired.

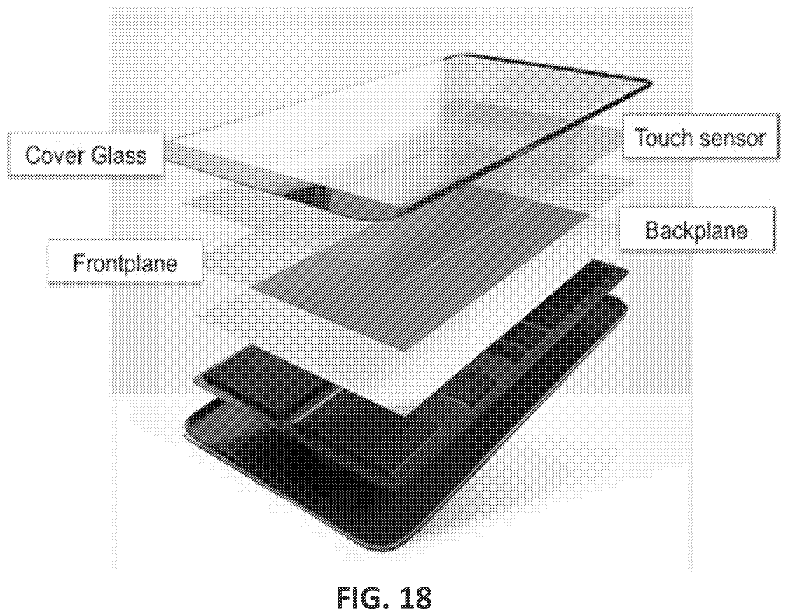

A photograph of a phantom is shown in FIG. 16A, where a looped polyethylene tube filled with the ICG solution was embedded in the tissue mimicking material and suspended using fishing lines. 3D image reconstruction was performed and then the volumetric data was rendered using a medical image viewing software (Osirix, Pixmeo SARL, Bernex, Switzerland) and displayed by using maximum intensity projection (MIP) (FIG. 16B). The ICG tube and the fishing line node could be seen in the rendered 3D image.

The effect of the silicon plate absorption has been discussed above. Although the artifact introduced by the silicon plate is not significant, and no damage has been observed on the silicon plate due to the absorption of the output laser energy into the CMUT up to 20 mJ/cm², it may be desired to have a more transparent device for backward mode PAI to improve the image quality. CMUT fabrication technologies enable a wide selection of processing materials. The transparency of the device may be further improved by replacing the silicon plate with a more transparent material such as silicon nitride, ITO, glass, and the like.

The demonstrated CMUT resonates at approximately 3.62 MHz in air and operates at approximately 1.4 MHz, 105% fractional bandwidth in immersion due to medium damping. CMUT technology can provide a wide range of center frequency, broad bandwidth, and good receive sensitivity, and therefore is particularly suitable for photoacoustic imaging. In the presented approach, the pencil lead cross-sectional image and the ICG tube volumetric image were formed by mechanically scanning a single CMUT element. To further improve the image quality, 1D and 2D CMUT arrays can be fabricated using the same approach to improve the image quality and acquisition time. Furthermore, a lens can be designed to uniformly distribute the light on the array from the backside.

Biosensor Applications: A CMUT can be configured as a gravimetric sensor with a selective functionalization layer on top of the vibrating plate structure. For this kind of a sensor the vibration frequency shifts down as the target molecules bind (or get adsorbed) on the surface of the functionalization layer due to the mass loading. Such a sensor could be designed to operate for sensing in a gaseous medium or in a liquid medium to serve as a gas sensor or biosensor (possibly in a microfluidic channel). The vibration frequency of the plate could be measured using electrical circuits such as oscillators or by optical interrogation based on interferometric detection. For optical detection the light beam could be introduced from the bottom side of the transducer through the transparent bottom electrode. The vibrating plate would be made to reflect the light back for detection of the phase shifts between the incoming and reflected beams to measure the vibration frequency and amplitude. One of the advantages that this scheme offers is to avoid the interaction of the light beam with the biological sample on the top side of the vibrating plate.

Display Embedded Applications: In the current information age, we spend a significant amount of our time looking at an electronic display, i.e., a computer, a smartphone, a tablet, or a TV. Our direct interaction with these displays is mostly based on receiving the visual information and in some cases providing input using a touch sensor integrated with the display. For audio interaction there are separate microphones and loudspeakers on these devices. For authentication, there are fingerprint scanners based on capacitive, optical, or ultrasonic sensors. Touch sensor seems to be the only standard sensor device closely integrated with the display. Direct integration of other sensors and physical interfaces with electronic displays is required for scaling the systems employing these displays as well as for enhancing the way we interact with the electronic devices around us.

The described optically transparent micromachined ultrasonic transducers can be directly integrated on or within the glass substrates used in electronic displays. These ultrasonic transducers enable a variety of physical interfaces directly on the display. Some examples for these potential applications include directional sound sources, fingerprint scanners, touch sensors with force sensing, wideband microphones, gesture recognition interfaces, and the like.

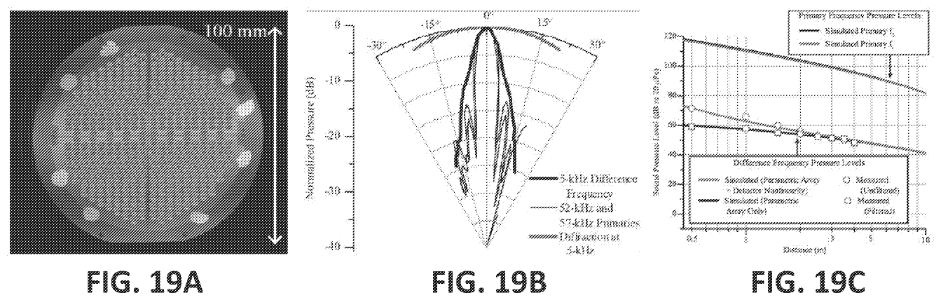

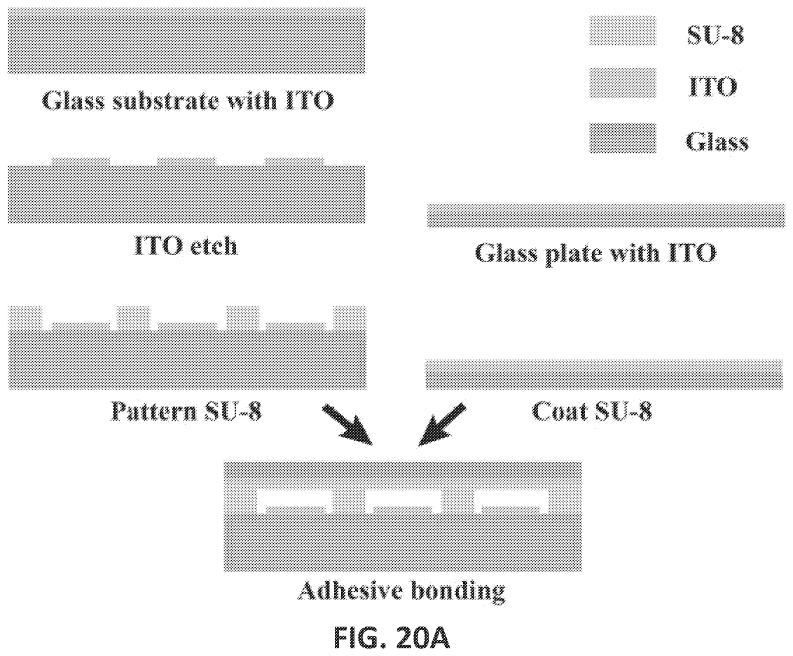

Regarding a directional sound source, modulated ultrasound emitted at a high frequency can be demodulated when passing through a nonlinear medium. Since the sound emission at higher frequency (shorter wavelength) can be made directional the demodulated low-frequency sound will only be audible to the person directly in front of the source. Using an array of such devices a 3D virtual surround sound effect can be created. As an exemplary demonstration of a transparent ultrasonic transducer embedded in display glass, a surround sound source application was selected to set the specifications for an exemplary device (see FIG. 17, which shows a transparent parametric ultrasonic array embedded in display glass can be used to generate directed beams in different directions to create sound spots by nonlinear demodulation). It is to be noted that the disclosed approach is different than just bonding an ultrasonic transducer on the display glass. The ultrasonic transducer arrays are implemented directly in display cover glass, which is an approach that is scalable to large area panels. The construct of high-end liquid crystal display panels includes several layers of glass substrates (see FIG. 18 as an example of the layers that comprise a typical flat-panel display). For the implementation of an embedded transducer (e.g., a surround sound source), the cover glass presents itself as a suitable layer in the stack as long as the transducers are sufficiently transparent not to interfere with the image on the display.

To generate directional low-frequency sound with a parametric array, the transducer transmits an amplitude-modulated ultrasound carrier wave. As this wave propagates, it becomes increasingly distorted due to the nonlinearities of sound propagation. These nonlinearities result in the generation of harmonic components in the audio frequency band (in addition to higher harmonics). This process is often referred to as self-demodulation. The beamwidth of the self-demodulated sound is similar to that of the carrier wave, yet at a much lower frequency. In other words, the beamwidth of the demodulated sound is much narrower than it would be had the sound been radiated directly by the transducer. For example, consider a transducer that transmits an amplitude-modulated ultrasound signal with a carrier frequency f₀ and modulation frequency f_{diff}/2. The modulated signal consists of ultrasonic frequencies f₁=f₀−f_{diff}/2 and f₂=f₀+f_{diff}/2. f₁ and f₂ are referred to as the primary frequencies. As this signal propagates, self-demodulation results in audible sound at the difference frequency f_{diff}=|f₂−f₁|. The challenge of transmitting sound with parametric arrays in air is to generate ultrasound waves with sufficient intensity to produce desirable sound pressure levels in the audio band.

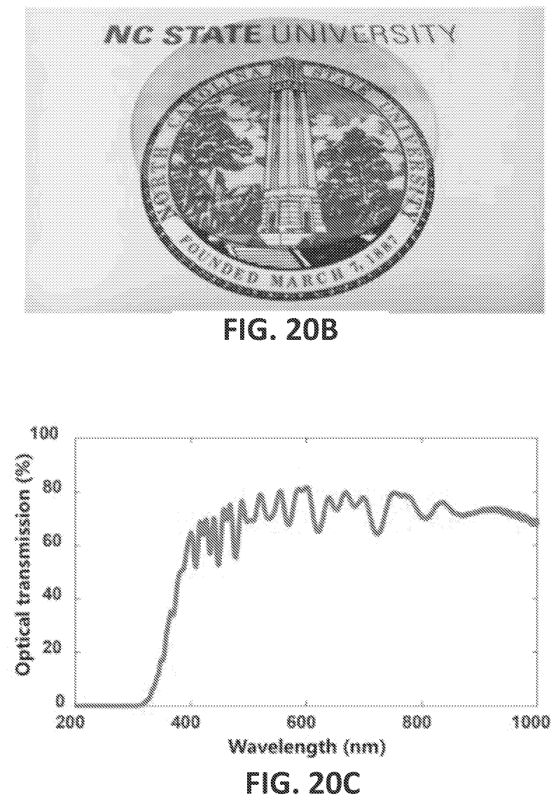

It has been demonstrated that CMUTs are capable of generating sufficient intensity and couple energy to air efficiently to implement parametric arrays (see, for example, Wygant, Ira O., Mario Kupnik, Jeffry C. Windsor, Wayne M. Wright, Mark S. Wochner, Goksen G. Yaralioglu, Mark F Hamilton, and Butrus T. Khuri-Yakub. “50 kHz capacitive micromachined ultrasonic transducers for generation of highly directional sound with parametric arrays.” IEEE transactions on ultrasonics, ferroelectrics, and frequency control 56, no. 1 (2009): 193-203, incorporated by reference). For example, for a silicon-based CMUT parametric array (see FIG. 19A), beam patterns were measured for primary and difference frequencies at 3-m distance. The device was driven with the sum of 52 kHz and 57 kHz 100-V peak-to-peak sinusoidal signals to create a 5-kHz parametric array. On-axis 3 m from the CMUT source, the sound pressure levels of the primary frequencies were 100 dB and 108 dB relative to 20 μPa RMS, respectively. The sound pressure level of the 5-kHz difference frequency was 58 dB (see FIG. 19B). The diffraction curve shows the 5-kHz sound beam profile had that frequency of sound been directly radiated by the source. Comparison of the diffraction curve with the measured sound beam profile illustrates that the parametric array results in a much narrower beam of sound than conventional sound transmission. Sound pressure levels of the primaries (f₁=48.5 kHz, f₂=53.5 kHz) and 5-kHz difference frequency were measured as a function of distance from the CMUT (see FIG. 19C). Close to the CMUT, where the sound pressure levels of the primary waves were high, detector nonlinearity was the dominant source of measured sound level at the difference frequency. An acoustic low-pass filter placed in front of the microphone to attenuate the sound at the primary frequencies incident on the microphone was used to eliminate the effects of detector nonlinearity. The remaining sound in that case comes from the parametric array. This work demonstrates the CMUT technology is capable of meeting the specifications required to generate directed sound using a parametric array. The glass-based fabrication schemes described herein allow similar or better performance to be achieved, as well as to implement arrays that can be fabricated on large transparent panels.

Regarding a fingerprint scanner, one way of scanning a fingerprint is to bounce acoustic waves back off the fingertip. Since the acoustic impedance of the ridges and air-filled valleys are different, the returned echo signal characteristics from these regions would also be different. A dense high frequency (>20 MHz) array of ultrasonic transducers can capture a 3D map of the fingerprint at once. This technique is immune to contamination and moisture on the finger, which are known problems for the widely used capacitive sensors.

Regarding a touch sensor with force sensing, the kind of transducer array described for fingerprint scanning can also be used as a touch sensor. The basic building block of a capacitive micromachined ultrasonic transducer (CMUT) is a capacitor, which has a movable top plate. This structure is also capable of measuring the static pressure applied. Hence, the described touch sensor would also be able to measure the applied force with high spatial resolution.

In regard to a wideband microphone, either a conventional condenser microphone can be built in glass or CMUTs can be used with a radio-frequency or optical detection scheme to achieve a flat mechanical response from DC up to ultrasonic frequencies.

Regarding gesture recognition interface, the described transducer array on the display can be used to emit ultrasound through the air and ‘listen’ to the echo signals bouncing back from user's hands for touchless control.

### Alternate Fabrication Processes

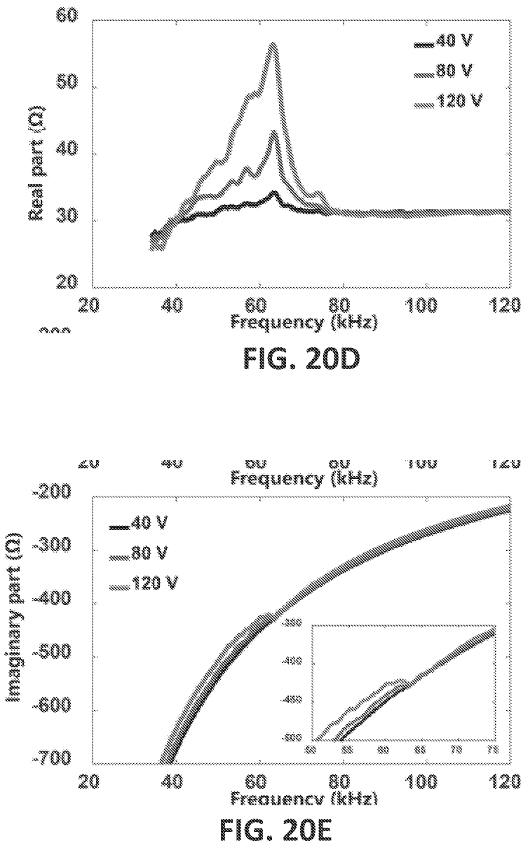

It is to be appreciated that the disclosed methods and materials for fabricating a transparent CMUT using anodic bonding (above), are not the only methods and materials for fabricating such a CMUT. For example, FIG. 20 illustrates an optically transparent air-coupled capacitive micromachined ultrasonic transducer (CMUT) fabricated using adhesive bonding. The exemplary transparent CMUT was fabricated by a two-mask process using adhesive bonding (see FIG. 20A), specifically for display-based air-coupled applications. An approximately 1-mm-thick, 100-mm-diameter glass wafer with an approximately 200-nm ITO coating was used as the starting substrate. The ITO was etched to form the bottom electrodes and then an approximately 4.5-μm thick photoresist [in this instance, SU-8, though other photoresists that are adhesive, substantially optically transparent, controllable (definable gap-thickness), have a bondable surface quality and desired electrical characteristics (e.g., high dielectric constant) can be used] was spun and patterned to serve as the post and also the base for adhesive bonding. An approximately 175-μm-thick glass wafer with an approximately 200-nm ITO coating was used as the top plate wafer. An approximately 1-μm thick SU-8 layer was coated on the ITO to serve as an insulation layer. The plate wafer was flipped and bonded on the thick wafer at approximately 120° C. under approximately 0.3-MPa pressure in vacuum.

The completed wafer is a single CMUT element. The wafer was placed on a “NC State University” logo to show the transparency (FIG. 20B). The average optical transmission of the device is measured as ˜70% in the 400-1000-nm wavelength range (FIG. 20C). The electrical input impedance was measured in air (FIG. 20D (real) and FIG. 20E (imaginary)). The resonant frequency of the fabricated device is ˜62 kHz and the series resistance is ˜30Ω.

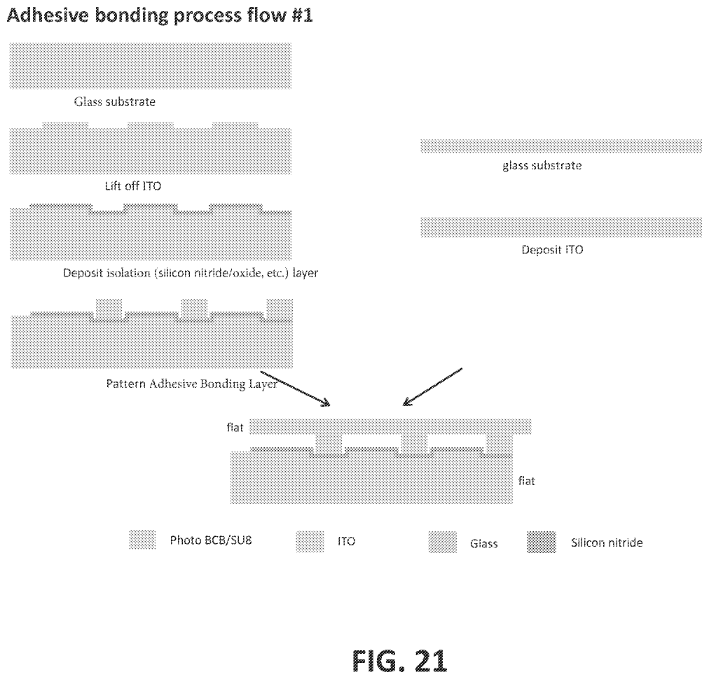

FIGS. 21-24 illustrate additional alternative processes and material for fabrication of a substantially transparent CMUT using adhesive bonding. Generally, in regard to FIGS. 21-27, the initial substrates are a thick bottom glass (e.g. 700-μm) and a thin top plate glass (e.g. 30-μm), both coated with ITO conducting film (e.g. 200-nm). The top plate glass can be implemented with a handle wafer for easier handling, which can be removed after bonding. A patternable (photo-sensitive or etchable) adhesive polymer (e.g., BCB, SU8) is used to create the cavities of CMUTs and is also used for adhesively bonding with the thin plate. If the adhesive material is not photo patternable, it can also be spray coated using a stencil. The bottom ITO electrode can be patterned to reduce parasitics, or leave as a uniform layer for simplicity. An insulation layer between the electrodes can be implemented using CMOS compatible dielectric material (i.e. silicon nitride) or using a thin adhesive polymer layer for a stronger bonding. The CMUTs could be fabricated with air-backing by leaving the outlet channels open or with vacuum-backing by having the outlet channels sealed.

FIGS. 21-24 illustrate four example implementations using adhesive bonding to fabricate air CMUT based on the above statements.

FIG. 21 illustrates a process flow for making transparent micromachined ultrasonic transducers by using adhesive wafer bonding. The insulation layer is placed on top of the bottom electrode.

FIG. 22 describes a process flow for making transparent micromachined ultrasonic transducers by using adhesive wafer bonding. The insulation layer is placed on the bottom side of the vibrating plate and is made of a polymer layer.

FIG. 23 describes a process flow for making transparent micromachined ultrasonic transducers by using adhesive wafer bonding. In this particular process the bottom electrode is not patterned.

FIG. 24 describes a process flow for making transparent micromachined ultrasonic transducers by using adhesive wafer bonding. In this particular process, glass substrate is etched to create cavities and ITO is formed inside the cavities. This eliminates the requirement of patterning the adhesive bonding layer. The adhesive bonding layer can be simply formed on the other substrate by spin or spray coating and it can be directly bonded to the glass posts.

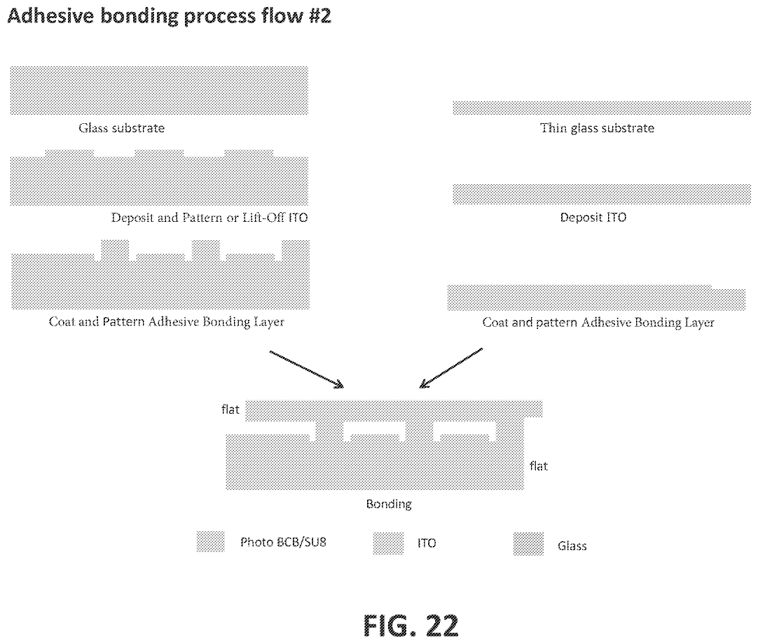

FIGS. 25-27 illustrate additional alternative processes and material for fabrication of a substantially transparent CMUT using anodic bonding. The initial substrates are a thick glass substrate and a thin top plate glass (e.g. 30-μm) which are anodically bondable (e.g. B33 glass). The top plate glass can be implemented with a handle wafer for easier handling, which can be removed after bonding. CMUT cavities are created by etching the glass (wet etch/dry etch). ITO bottom electrodes are patterned inside the cavities (e.g. by sputtering and lift-off). ITO top electrodes are uniformly deposited on the plate glass. A dielectric material can be implemented be can electrodes to prevent short circuit during CMUT operation. An intermediate anodically bondable glass can be used on bottom or top wafer to facilitate anodic bonding and also serve as the insulation layer.

FIGS. 25-27 illustrate three possible implementations using anodic bonding to fabricate air CMUT based on the above comments. FIG. 25 illustrates a process flow for making transparent micromachined ultrasonic transducers by using anodic bonding. In this particular flow, the glass vibrating plate is formed by sputtering bondable glass on top of a silicon wafer before the bonding. The silicon carrier wafer is later removed. The device structure does not have an insulating layer between the two electrodes.

FIG. 26 illustrates a process flow for making transparent micromachined ultrasonic transducers by using anodic bonding. In this particular flow, the glass vibrating plate is formed by sputtering bondable glass on top of a silicon wafer before the bonding. The silicon carrier wafer is later removed. The device structure includes an insulating layer between the two electrodes. This insulating layer is formed by depositing thin bondable glass on top of the conducting electrode layer.

FIG. 27 illustrates a process flow for making transparent micromachined ultrasonic transducers by using anodic bonding. In this particular flow, the glass vibrating plate is formed by sputtering bondable glass on top of a silicon wafer before the bonding. The silicon carrier wafer is later removed. The device structure includes an insulating layer between the two electrodes. This insulating layer is formed by sputtering bondable glass (as insulation and bonding intermediate layer) on top of the bottom electrode.

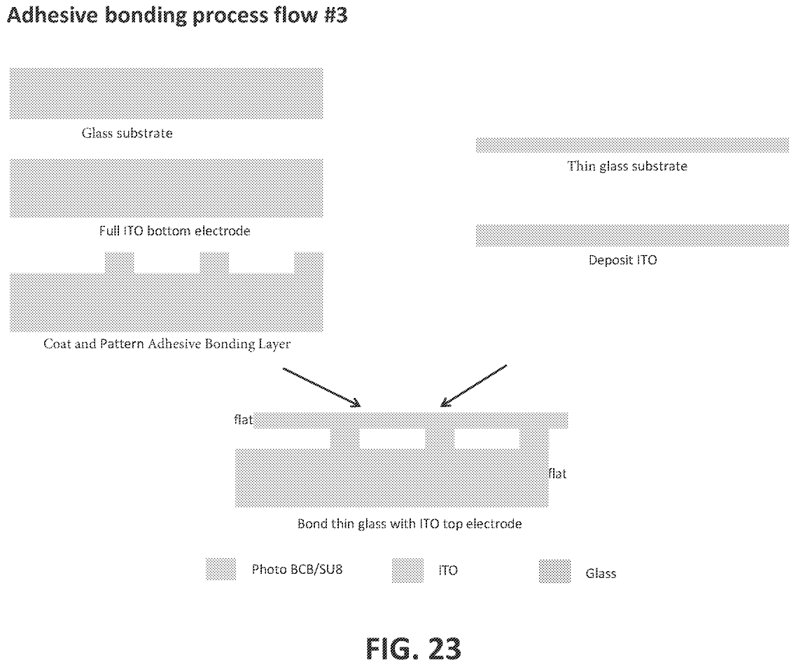

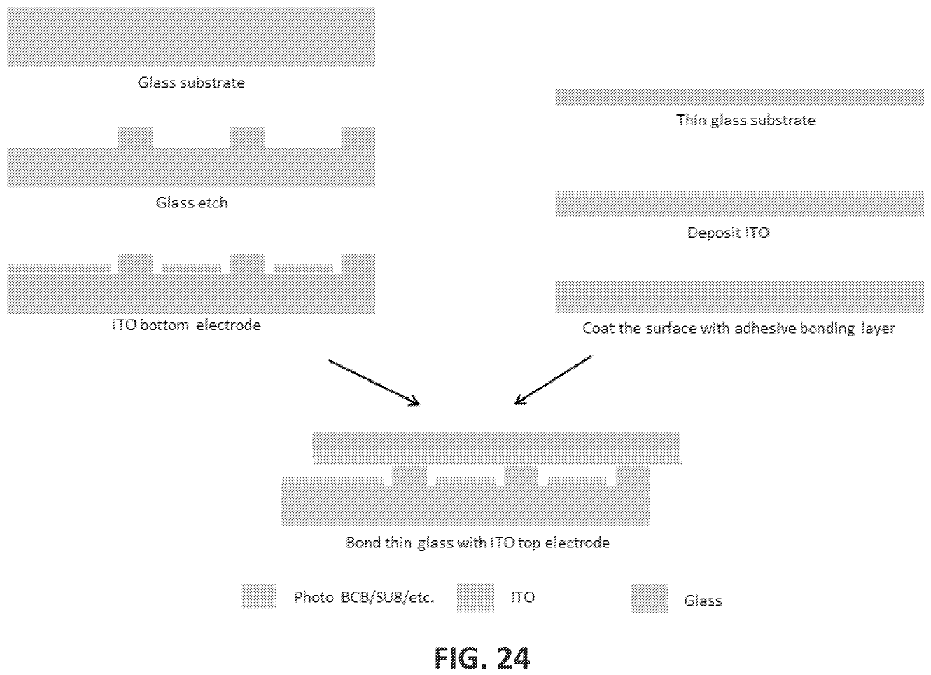

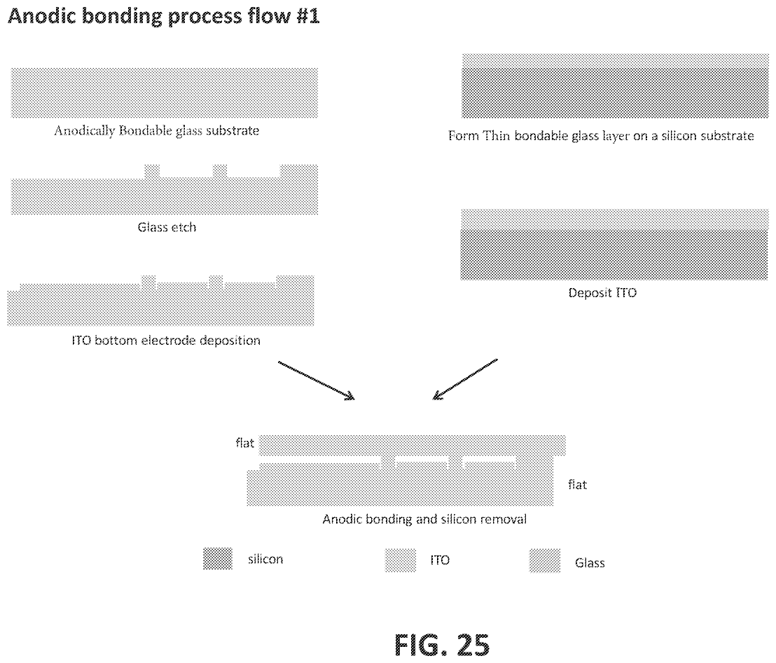

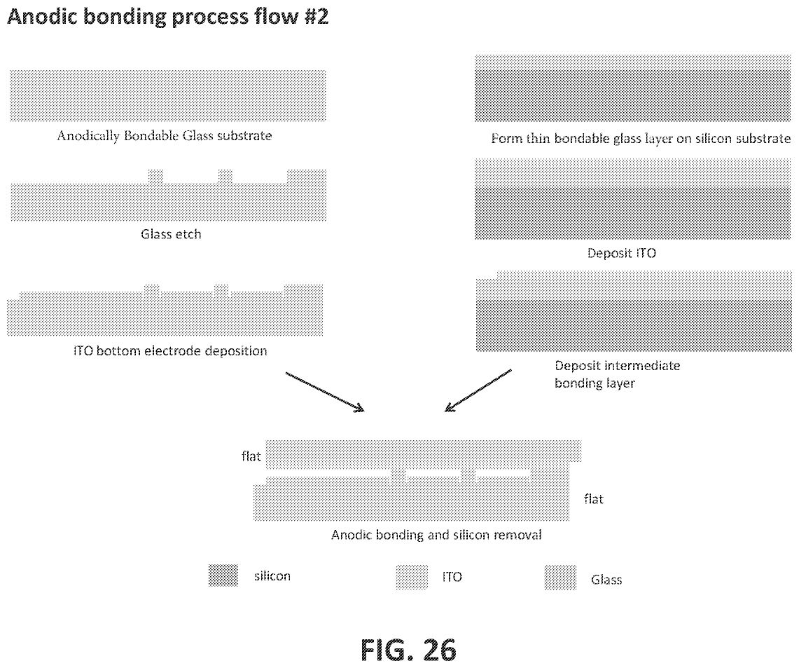

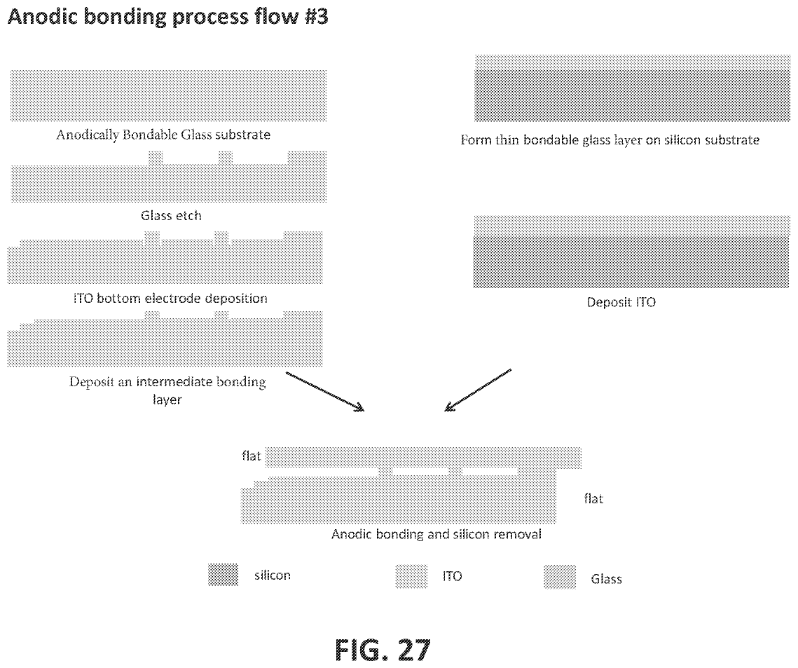

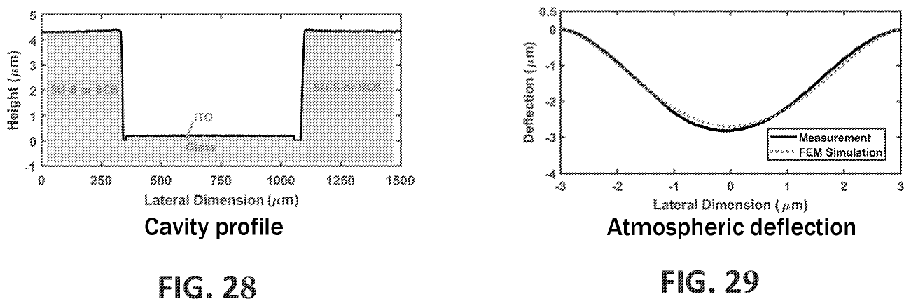

FIG. 28 illustrates an exemplary cavity profile for a CMUT fabricated according to the processes described in FIGS. 21-27. FIG. 29 is a graph that illustrates atmospheric deflection for a CMUT fabricated according to the processes described in FIGS. 21-27. FIG. 30 is an image of a CMUT wafer created using the SU-8 bonding process. FIG. 31 is an image of a CMUT wafer created using the BCB bonding process. FIG. 32 is a graph that illustrates CMUT transmittance with the SU-8 process. FIG. 33 is a graph that illustrates CMUT transmittance with the BCB process.

### Air-Coupled CMUTS

A. CMUTs for Air Coupled Ultrasound with Improved Bandwidth

In wafer-bonded CMUTs with plates made of single-crystal silicon from silicon-on-insulator (SOI) wafers and evacuated cavities, the bandwidth is low when operated in air. Typical quality factors range from Q approximately 10 to 400, depending on the transducer geometry, biasing condition, and thickness uniformity of the SOI wafer used (polished or epitaxial grown).

In previously designed CMUTs for chemical sensing applications, an impressive quality factor of 400 was measured for 1000 CMUT cells, connected and operated in parallel (see, for example, “CMUTs for air coupled ultrasound with improved bandwidth,” M Kupnik, M C Ho, S Vaithilingam, B T Khuri-Yakub—Ultrasonics Symposium (IUS), 2011 IEEE International, 2011; Shuai Na, L. L. P. Wong, A. I. H. Chen, Z. Li, M. Macecek and J. T. W. Yeow, “A CMUT array based on annular cell geometry for air-coupled applications,” 2016 IEEE International Ultrasonics Symposium (IUS), Tours, 2016, pp. 1-4; and M. Kupnik, S. Vaithilingam, K. Torashima, I. O. Wygant, and B. T. Khuri-Yakub, “CMUT fabrication based on a thick buried oxide layer,” in Proc. IEEE Ultrasonics Symposium, pp. 547-550, 2010, which are all incorporated by reference). Many other applications, however, require a low quality factor for airborne ultrasound applications. Examples are range finding applications, ultrasonic transit-time gas flow meters for metering dynamic gas flows, anemometry applications, and various other ultrasound-based sensing applications.

B. Wideband Spiral CMUTs for Air Coupled Applications

In general, a CMUT unit cell is comprised of a clamped plate that is suspended over a circular or a square cavity. A CMUT element is a combination of many cells connected in parallel. Thus, the operating frequency is mainly determined by the size of the suspended plate and its thickness. CMUTs with all cell radii identical have less than 1% fractional bandwidth (FBW) in air. Bandwidth can be improved by varying cell radii over the active transducer area. Each cell operates at a distinct frequency and when they operate together the bandwidth becomes broader. The cell radii distribution can be weighted by the transmit (displacement) sensitivity of each cell. Up to 2.5% 6 dB FBW is demonstrated. Transmit sensitivity is decreased as the operating voltage causes different displacement on each cell type. Typically, higher frequency cells are smaller in size, so the deflection is less at the same voltage as compared to low frequency ones.

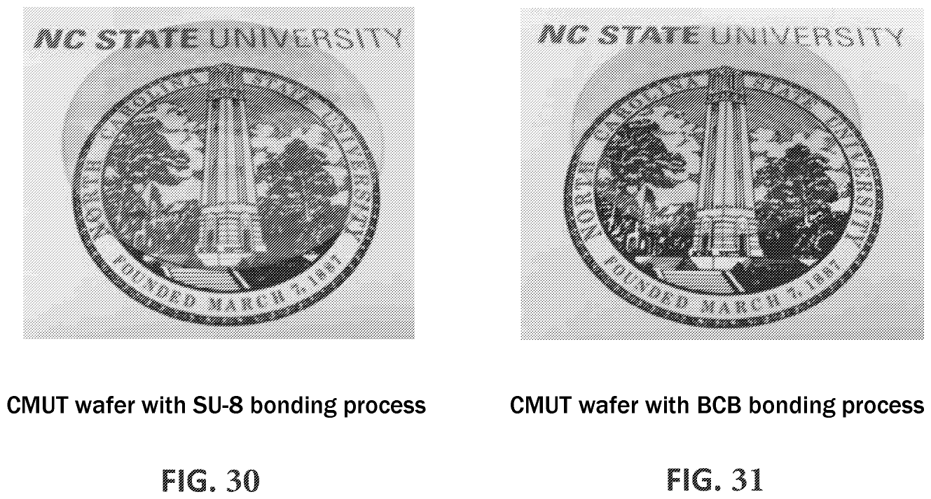

Transmit sensitivity can be improved by using annular CMUT arrays that demonstrate high volumetric displacement as compared to circular or square type cells. FIG. 34 shows a known an annular CMUT element comprised of three rings each with different widths (W) (see Shuai Na, L. L. P. Wong, A. I. H. Chen, Z. Li, M. Macecek and J. T. W. Yeow, “A CMUT array based on annular cell geometry for air-coupled applications,” 2016 IEEE International Ultrasonics Symposium (IUS), Tours, 2016, pp. 1-4, incorporated by reference, as an exemplary annular cell CMUT).

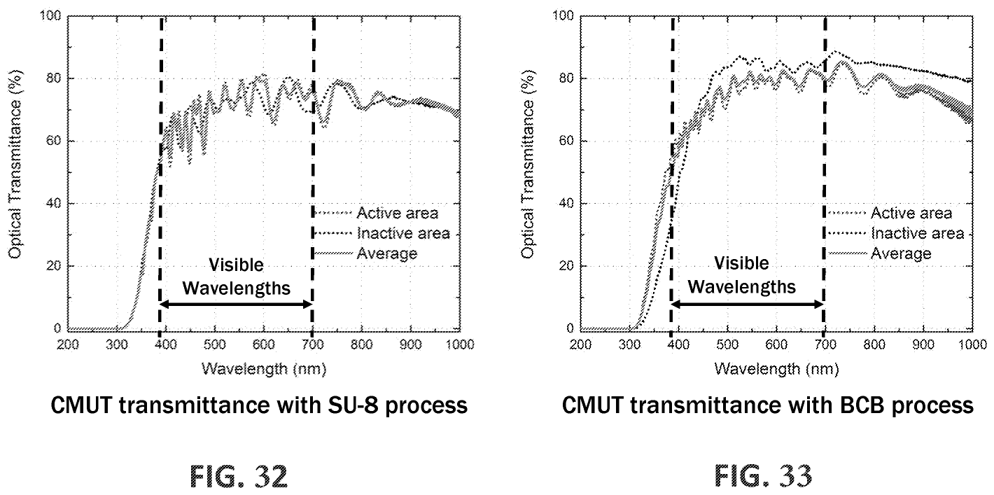

Described herein is a spiral shape element with a variation in the width (FIG. 35). The structure provides more uniform frequency distribution over the active area that results in a wideband operation.

For a given aperture size, the final width of the very inner turn (W1) is selected to provide the lowest frequency component of the transmit wave. The width gets uniformly smaller on each turn so that the final width of the spiral (W2) provides the highest frequency component of the transmit wave. Or the opposite scheme (smallest width at the very inner turn and largest width as the final width of the spiral) can be used depending on the required aperture size and transmit sensitivity. The number of turns can be increased using a smaller and a thinner plate (keeping the operating frequency within the operating range). The cavity depth of each turn can be adjusted by separate etching steps, requiring additional masks. The cavity depth (gap) of the higher frequency region can be smaller so that the displacement over the aperture is more uniform at the same operating voltage.

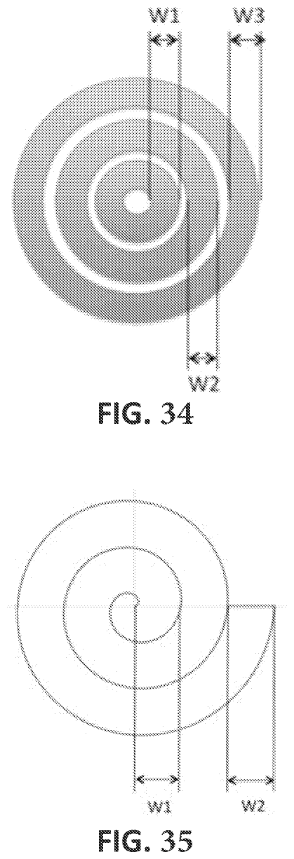

A design example is shown in FIG. 36. Parameters for this exemplary CMUT include plate material: D263T Glass; thickness: 175 um; density: 2510 kg m⁻³; Young's Modulus: 72 GPa; Poisson's ratio: 0.208. the CMUT is a spiral with polar equation r=W×θ with 4 turns: θ: [0,8π] with a step of 2π/30; W: [0, W1] with a step of W1/30; (1^{st} turn); [W1, W1−Δ] with a step of (W1−Δ)/30; (2^{nd} turn); [W1−Δ, W1−2Δ] with a step of (W1−2Δ)/30; (3^{rd} turn); and [W1−2Δ, W1−3Δ] with a step of (W1−3Δ)/30(4^{th} turn), where W1=4800 um and Δ=200 um.

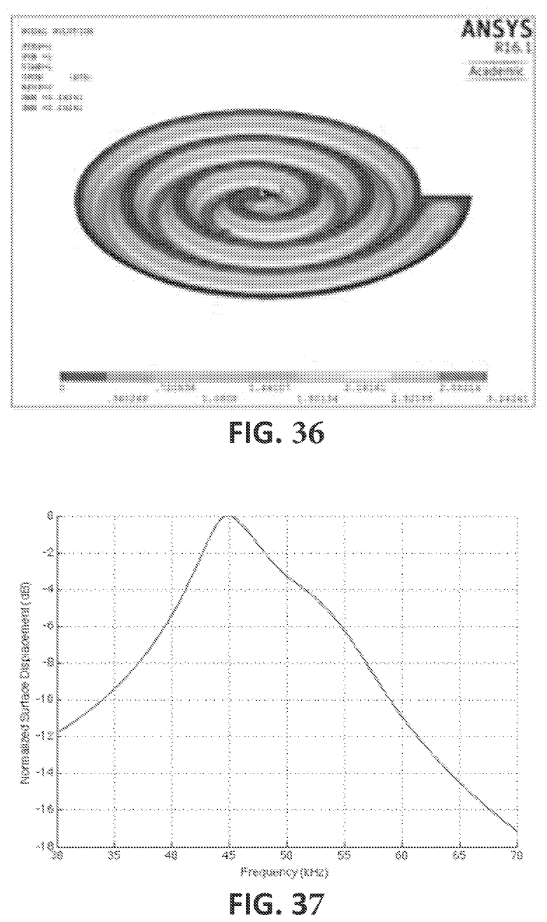

The simulated bandwidth using finite element simulation is shown in FIG. 37. The design operates at 45 kHz with a fractional bandwidth of 17%.

### CONCLUSION

Implementations of the disclosed CMUT can be used in, for example, ultrasound imaging, ultrasound therapy, ultrasound-based sensing, chemical gas sensors, photoacoustic imaging transducers, biosensors, directional sound source embedded in display glass, fingerprint scanner embedded in display glass, touch sensor with force sensing in display glass, wideband microphone embedded in display glass, gesture recognition interface embedded in display glass and the like wherein the acoustic and ultrasonic transducers can be embedded in the cover glass of display devices used in television sets, computer monitors, tablets, mobile phones, etc.

For example, the described transducers embedded in glass can be used for a combination of the described applications. For example, the display-embedded ultrasonic transducers can be used to scan and map the objects in a room, find the people, animals, and sound reflectors. Most displays now also have an embedded camera as well. So, the visual data can also be used with the reflection-mode acoustic scan. This information can be used to generate a 3D virtual surround sound experience based on the location of sound reflectors and listeners. When ultrasound is used to create directional sound, the animals could be avoided, especially if the used ultrasound frequency is in the audible range for animals Other example applications include individual audio messaging that can be embedded in the display by recognizing the person to deliver a message and send the message by directed sound. The array sound sources can also be formed to generate sound in the audible frequencies. This will act as a loudspeaker that can steer the sound without using the parametric array concept. For a mobile phone or a tablet or any other similar device with an integrated display sound can be generated only directed to the person's ears in a stereo fashion, so that the sound is not heard by other people in the area. Ultrasound transducers can be implemented in window glass as sensors or sources. These transducers can be implemented on automobile head and taillights for distance measurements and range finding. For neural applications a transparent transducer could enable combination of optogenetic and acoustogenetic approaches for neural stimulation as well as direct acoustic stimulation.

While the methods and systems have been described in connection with preferred embodiments and specific examples, it is not intended that the scope be limited to the particular embodiments set forth, as the embodiments herein are intended in all respects to be illustrative rather than restrictive.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

Throughout this application, various publications are referenced. The disclosures of these publications in their entireties are hereby incorporated by reference into this application in order to more fully describe the state of the art to which the methods and systems pertain.

It will be apparent to those skilled in the art that various modifications and variations can be made without departing from the scope or spirit. Other embodiments will be apparent to those skilled in the art from consideration of the specification and practice disclosed herein. It is intended that the specification and examples be considered as exemplary only, with a true scope and spirit being indicated by the following claims.

1. A substantially optically-transparent capacitive micromachined ultrasonic transducer (CMUT) comprising:
a substrate having a cavity, wherein the substrate is comprised of substantially optically-transparent material;
a patterned conductive bottom electrode situated within the cavity of the substrate, wherein the patterned conductive bottom electrode is comprised of substantially optically-transparent material; and
a vibrating plate comprising at least a conducting layer, wherein the vibrating plate is bonded to the substrate and wherein the vibrating plate is at least partially comprised of substantially optically-transparent material.

2. The substantially optically-transparent CMUT of claim 1, wherein a pressure inside the cavity is less than or equal to atmospheric pressure.

3. The substantially optically-transparent CMUT of claim 1, wherein a pressure inside the cavity is greater than atmospheric pressure.

4. The substantially optically-transparent CMUT of claim 1, wherein the substantially optically-transparent material of the substrate is compatible with adhesive bonding or anodic bonding, and wherein the substrate is selected from the group consisting of glass, quartz, and fused silica.

5.-6. (canceled)

7. The substantially optically-transparent CMUT of claim 4, wherein the substantially optically-transparent material of the substrate comprises a flexible transparent material.

8. The substantially optically-transparent CMUT of claim 1, wherein an air-tight seal is formed between the substrate and the vibrating plate.

9. The substantially optically-transparent CMUT of claim 1, wherein spacers are formed in the substrate to form an insulating space between the patterned conductive bottom electrode and the conducting layer of the vibrating plate.

10. The substantially optically-transparent CMUT of claim 1, further comprising a substantially optically-transparent insulating layer, wherein the insulating layer is situated substantially between the patterned conductive bottom electrode and the conducting layer of the vibrating plate.

11. The substantially optically-transparent CMUT of claim 10, wherein the insulating layer is attached to the bottom of the conducting layer of the vibrating plate or located on top of the patterned conductive bottom electrode.

12. (canceled)

13. The substantially optically-transparent CMUT of claim 10, wherein the insulating layer comprises silicon nitride, Hafnium(IV) oxide, or another high dielectric constant material.

14. (canceled)

15. The substantially optically-transparent CMUT of claim 13, wherein the insulating layer further comprises BCB or SU-8 adhesive or another adhesive material used for bonding.

16-17. (canceled)

18. The substantially optically-transparent CMUT of claim 1, wherein the vibrating plate further comprises a vibrating plate conductive electrode that is situated on a top side of the vibrating plate or on bottom side of the vibrating plate.

19.-20. (canceled)

21. The substantially optically-transparent CMUT of claim 1, wherein the conducting layer of the vibrating plate comprises a substantially-transparent conductive material.

22. The substantially optically-transparent CMUT of claim 21, wherein the vibrating plate further comprises a vibrating plate insulating layer, and wherein the vibrating plate insulating layer comprises silicon, silicon nitride, silicon dioxide or glass.

23.-24. (canceled)

25. The substantially optically-transparent CMUT of claim 1, wherein the substrate has a plurality of cavities, each cavity having the patterned conductive bottom electrode, wherein one or more of the plurality of cavities are vacuum sealed.

26. The substantially optically-transparent CMUT of claim 1, wherein the substrate has a plurality of cavities, each cavity having the patterned conductive bottom electrode, wherein the patterned conductive bottom electrodes of the plurality of cavities are electrically connected to one another.

27. The substantially optically-transparent CMUT of claim 1, wherein the substrate has a plurality of cavities, each cavity having the patterned conductive bottom electrode, and
wherein the substantially optically-transparent CMUT further comprises:
one or more conductive vias that are situated through the substrate, wherein the one or more vias are used to electrically connect with at least one of the patterned conductive bottom electrodes, the conductive layer of the vibrating plate, and a conductive electrode of the vibrating plate.

28. The substantially optically-transparent CMUT of claim 1, wherein the patterned conductive bottom electrode is comprised of indium-tin-oxide (ITO) or another conductive material that is substantially optically-transparent.

29.-32. (canceled)

33. The substantially optically-transparent CMUT of claim 1, wherein the polymer comprises a substantially optically-transparent photoresist or a substantially optically-transparent non-photosensitive polymer, and wherein the substantially optically-transparent photoresist is selected from the group consisting of photosensitive BCB, SU-8, and PermiNex.

34.-43. (canceled)

44. The substantially optically-transparent CMUT of claim 1, wherein the CMUT is configured as an annular CMUT or a spiral CMUT with varying width.

45.-47. (canceled)
